(19) United States
(12) Patent Application Publication
(10) Pub. No.: US 2012/0206658 A1
(43) Pub. Date: Aug. 16, 2012

(54) ACTIVE MATRIX SUBSTRATE, LIQUID CRYSTAL PANEL, AND TELEVISION RECEIVER

(75) Inventor: Hidefumi Yoshida, Osaka-shi (JP)

(73) Assignee: SHARP KABUSHIKI KAISHA, Osaka-shi, Osaka (JP)

(21) Appl. No.: 13/501,099

(22) PCT Filed: Oct. 21, 2010
(86) PCT No.: PCT/JP2010/068627

§ 371 Date: Apr. 10, 2012

(30) Foreign Application Priority Data
Oct. 23, 2009 (JP) 2009-244475

(51) Int. Cl. H04N 5/50; G02F 1/136; H01L 27/088

(52) U.S. Cl. 348/731; 257/59; 257/71; 349/43; 257/E27.06; 348/E05.097

(57) ABSTRACT

An active matrix substrate including: a scanning signal line (Gn); a data signal line (15x); a first transistor and a second transistor which are connected with the scanning signal line and the data signal line; a third transistor connected with a scanning signal line (Gm) different from the scanning signal line (Gn), wherein a first pixel electrode (17a) connected with the first transistor; a second pixel electrode (17b) connected with the second transistor; a first capacitor electrode (37a) connected with the first pixel electrode; a second capacitor electrode (37b) connected with the second pixel electrode via the third transistor; and a relay electrode (7ab) are provided in each pixel area. The first and second capacitor electrodes are provided in a same layer as the data signal line. The relay electrode is provided in a same layer as the scanning signal lines. The relay electrode and each of the first and second capacitor electrodes overlap one another via a gate insulating film. This allows an increase in thickness of a channel protection film (interlayer insulating film).

### TECHNICAL FIELD

The present invention is related to an active matrix substrate and a liquid crystal panel which employ a pixel division system.

### BACKGROUND ART

As a technique for improving a viewing angle characteristic of a liquid crystal display device, a pixel division system is known in which two pixel electrodes (a bright pixel electrode corresponding to a bright subpixel and a dark pixel electrode corresponding to a dark subpixel) are provided to each pixel in a liquid crystal panel. The pixel division system can be classified into a 1-transistor capacitive coupling type and a 3-transistor capacitive coupling type. In the 1-transistor capacitive coupling type, (i) a bright pixel electrode is connected with a data signal line, via a transistor connected with a scanning signal line that is in a same row as the bright pixel electrode and (ii) a dark pixel electrode is connected with the bright pixel electrode, via a coupling capacitor. In the 3-transistor capacitive coupling type, (i) bright and dark pixel electrodes are connected with a data signal line, via respective different transistors connected with a scanning signal line that is in a same row as the bright and dark pixel electrodes and (ii) a capacitor electrode with which the bright pixel electrode constitutes a coupling capacitor is connected with the dark pixel electrode, via a transistor that is in a next row (see Patent Literature 1, for example). In the 1-transistor capacitive coupling type, the dark pixel electrode electrically floats. This causes pixel burn-in. In the 3-transistor capacitive coupling type, neither the bright pixel electrode nor the dark pixel electrode electrically floats and therefore pixel burn-in hardly occurs.

### CITATION LIST

### Patent Literature

Patent Literature 1
Japanese Patent Application Publication, Tokukai, No. 2008-33218 A (Publication Date: Feb. 14, 2008)

### SUMMARY OF INVENTION

### Technical Problem

However, in a conventional 1-transistor or 3-transistor capacitive coupling type liquid crystal panel, (i) a dark pixel electrode is connected with a capacitor electrode 169a (source metal) provided in a same layer as a data signal line and (ii) a bright pixel electrode 181 overlaps the capacitor electrode 169a via a channel protection film (interlayer insulating film) 170, so that a coupling capacitor is formed (see FIG. 22, for example). Such being the case, the channel protection film needs to be reduced in thickness to some extent in order to secure sufficient capacitance of the coupling capacitor. As such, it is impossible to increase a thickness of the channel protection film (by use of an organic insulating film, for example) so as to have a high aperture ratio structure in which a pixel electrode overlaps a data signal line or a scanning signal line. In addition, since the thickness of the channel protection film cannot be increased, (i) a parasitic capacitance between the pixel electrode and the data signal line or the scanning signal line cannot be reduced, (ii) the pixel electrode and the data signal line easily becomes short-circuited, and (iii) flatness of a surface on which the pixel electrode (e.g. ITO) is provided cannot be improved.

The present invention proposes a capacitive coupling type active matrix substrate in which a thickness of a channel protection film (interlayer insulating film) can be increased.

### Solution to Problem

An active matrix substrate of the present invention is an active matrix substrate including: a scanning signal line; a data signal line; a first transistor connected with the scanning signal line and the data signal line; a second transistor connected with the scanning signal line and the data signal line; and a third transistor connected with another scanning signal line which is different from the scanning signal line, wherein (i) a first pixel electrode connected with the first transistor, (ii) a second pixel electrode connected with the second transistor, (iii) a first capacitor electrode connected with the first pixel electrode, (iv) a second capacitor electrode connected with the second pixel electrode via the third transistor, and (v) a relay electrode are provided in each pixel area, the first capacitor electrode and the second capacitor electrode are provided in a same layer as the data signal line, the relay electrode is provided in a same layer as the scanning signal line and the another scanning signal line, and the relay electrode and each of the first capacitor electrode and the second capacitor electrode overlap each other, via a gate insulating film.

According to the configuration, a coupling capacitor of a bright pixel electrode and a dark pixel electrode in a 3-transistor capacitive coupling type liquid crystal panel can be formed by use of a combined capacitor of (i) a capacitor formed by the relay electrode and the first capacitor electrode and (ii) a capacitor formed by the relay electrode and the second capacitor electrode. The combined capacitor is a capacitor obtained by connecting the respective capacitors (i) and (ii) in series. This makes it possible to increase a thickness of a channel protection film (interlayer insulating film) so as to employ a high aperture ratio structure in which a pixel electrode overlaps a data signal line or a scanning signal line.

The active matrix substrate of the present invention can further include: retention capacitor wiring, a capacitor being formed by the retention capacitor wiring and the second capacitor electrode.

The active matrix substrate of the present invention can have a configuration in which an interlayer insulating film is provided on channels of the respective first through third transistors, the interlayer insulating film including an organic insulating film.

The active matrix substrate of the present invention can have a configuration in which the scanning signal line with which each of the first transistor and the second transistor is connected and the another scanning signal line with which the third transistor is connected are arranged adjacent to each other in this order along a scanning direction.

The active matrix substrate of the present invention can have a configuration in which each of the first pixel electrode and the second pixel electrode overlaps the data signal line.

The active matrix substrate of the present invention can have a configuration in which the data signal line meanders so that (i) the data signal line and (ii) an edge part of each of the first pixel electrode and the second pixel electrode overlap each other.

The active matrix substrate of the present invention can further include: a extraction electrode which is extracted from the first transistor so as to be connected with the first capacitor electrode; and a extraction electrode which is extracted from the third transistor so as to be connected with the second capacitor electrode, the first pixel electrode and the second pixel electrode being arranged along a longitudinal direction in the each pixel area, a lateral direction being a direction along which the scanning signal line and the another scanning signal line extend, the extraction electrodes, the first capacitor electrode, and the second capacitor electrode being provided so as to longitudinally run through the each pixel area.

The active matrix substrate of the present invention can further include: first retention capacitor wiring provided so as to traverse the first pixel electrode in a lateral direction, which is a direction along which the scanning signal line and the another scanning signal line extend; second retention capacitor wiring provided so as to traverse the second pixel electrode in the lateral direction; and third retention capacitor wiring provided so that (i) the third retention capacitor wiring and (ii) a gap between the first pixel electrode and the second pixel electrode overlap each other.

The active matrix substrate of the present invention can have a configuration in which the second capacitor electrode and the second retention capacitor wiring form a capacitor.

The active matrix substrate of the present invention can have a configuration in which (i) the first retention capacitor wiring or the second retention capacitor wiring and (ii) the third retention capacitor wiring are connected with each other.

The active matrix substrate of the present invention can have a configuration in which the first retention capacitor wiring and the third retention capacitor wiring are connected with each other in a pixel area corresponding to a color, and the second retention capacitor wiring and the third retention capacitor wiring are connected with each other in a pixel area corresponding to another color.

The active matrix substrate of the present invention can have a configuration in which the first retention capacitor wiring and the third retention capacitor wiring are connected with each other in one of two pixel areas adjacent to each other in the lateral direction, the second retention capacitor wiring and the third retention capacitor wiring are connected with each other in the other of the two pixel areas adjacent to each other in the lateral direction, the first retention capacitor wiring and the third retention capacitor wiring are connected with each other in one of two pixel areas adjacent to each other in a longitudinal direction, and the second retention capacitor wiring and the third retention capacitor wiring are connected with each other in the other of the two pixel areas adjacent to each other in the longitudinal direction.

The active matrix substrate of the present invention further includes: a fourth transistor connected with the scanning signal line with which each of the first transistor and the second transistor is connected; and a third pixel electrode connected with the fourth transistor.

The active matrix substrate of the present invention can have a configuration in which each of the first pixel electrode and the second pixel electrode has a fishbone shape.

An active matrix substrate of the present invention is an active matrix substrate including: a scanning signal line; a data signal line; and a first transistor connected with the scanning signal line and the data signal line, wherein (i) a first pixel electrode connected with the first transistor, (ii) a second pixel electrode, (iii) a first capacitor electrode connected with the first pixel electrode, (iv) a second capacitor electrode connected with the second pixel electrode, and (v) a relay electrode are provided in each pixel area (area corresponding to a color pixel), the first capacitor electrode and the second capacitor electrode are provided in a same layer as the data signal line, the relay electrode is provided in a same layer as the scanning signal line, and the relay electrode overlaps each of the first capacitor electrode and the second capacitor electrode via a gate insulating film.

An active matrix substrate of the present invention is an active matrix substrate including: a scanning signal line; a data signal line; a first transistor connected with the scanning signal line and the data signal line; a second transistor connected with the scanning signal line and the data signal line; a third transistor connected with another scanning signal line which is different from the scanning signal line; a fourth transistor connected with the scanning signal line with which each of the first transistor and the second transistor is connected; and retention capacitor wiring, wherein (i) a first pixel electrode connected with the first transistor, (ii) a second pixel electrode connected with the second transistor, (iii) a third pixel electrode connected with the fourth transistor, and (iv) a coupling electrode are provided in each pixel area, a capacitor being formed by the coupling electrode and each of the first pixel electrode and the retention capacitor wiring, and the coupling electrode is connected with the second pixel electrode, via the third transistor.

A liquid crystal panel of the present embodiment is a liquid crystal panel including: the active matrix substrate and a liquid crystal layer.

The liquid crystal panel of the present embodiment can have a configuration in which the liquid crystal layer is subjected to an alignment treatment by means of ultraviolet ray.

A television receiver of present invention is a television receiver including: a liquid crystal display device including the liquid crystal panel; and a tuner section for receiving a television broadcast.

### Advantageous Effects of Invention

As described above, the present invention makes it possible to realize a capacitive coupling type active matrix substrate in which a thickness of a channel protection film (interlayer insulating film) can be increased.

### BRIEF DESCRIPTION OF DRAWINGS

FIG. 1 is a plan view illustrating a configuration of a liquid crystal panel in accordance with Embodiment 1.

FIG. 2 is a circuit diagram illustrating a configuration of a liquid crystal panel in accordance with Embodiment 1.

FIG. 3 is a timing chart showing a method for driving the liquid crystal panel illustrated in FIG. 2.

FIG. 4 is a cross-sectional view taken along a line indicated by arrows of FIG. 1.

FIG. 5 is a plan view illustrating an area in which disclination (irregular orientation) is observed in a case where photo-aligned liquid crystal is used in the liquid crystal panel illustrated in FIG. 1.

FIG. 6 is a plan view illustrating another configuration of a liquid crystal panel in accordance with Embodiment 2.

FIG. 7 is a plan view illustrating still another configuration of a liquid crystal panel in accordance with Embodiment 2.

FIG. 8 is a circuit diagram illustrating a configuration of a liquid crystal panel in accordance with Embodiment 2.

FIG. 9 is a timing chart showing a method for driving the liquid crystal panel illustrated in FIG. 8.

FIG. 10 is a plan view illustrating a configuration of a liquid crystal panel in accordance with Embodiment 2.

FIG. 11 is a plan view illustrating an area in which disclination (irregular orientation) is generated in a case where photo-aligned liquid crystal is used in the liquid crystal panel illustrated in FIG. 10.

FIG. 12 is a plan view illustrating another configuration of a liquid crystal panel in accordance with Embodiment 2.

FIG. 13 is a plan view illustrating still another configuration of a liquid crystal panel in accordance with Embodiment 2.

FIG. 14 is a plan view illustrating a configuration of the liquid crystal panel illustrated in FIGS. 12 and 13.

FIG. 15 is a plan view illustrating still another configuration of a liquid crystal panel in accordance with Embodiment 2.

FIG. 16 is a plan view illustrating an area in which disclination (irregular orientation) is generated in the liquid crystal panel illustrated in FIG. 15.

FIG. 17 is a circuit diagram illustrating a configuration of a liquid crystal panel in accordance with Embodiment 3.

FIG. 18 is a timing chart showing a method for driving the liquid crystal panel illustrated in FIG. 17.

FIG. 19 is a plan view illustrating a configuration of a liquid crystal panel in accordance with Embodiment 3.

FIG. 20 is a cross-sectional view taken along a line indicated by arrows of FIG. 19.

FIG. 21 is a plan view illustrating an area in which disclination (irregular orientation) is generated in a case where photo-aligned liquid crystal is used in the liquid crystal panel illustrated in FIG. 19.

FIG. 22 is a schematic view illustrating a configuration of a conventional liquid crystal panel.

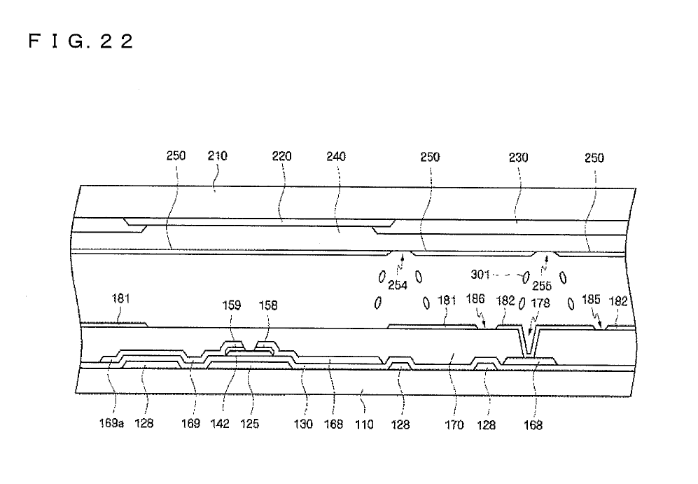

### DESCRIPTION OF EMBODIMENTS

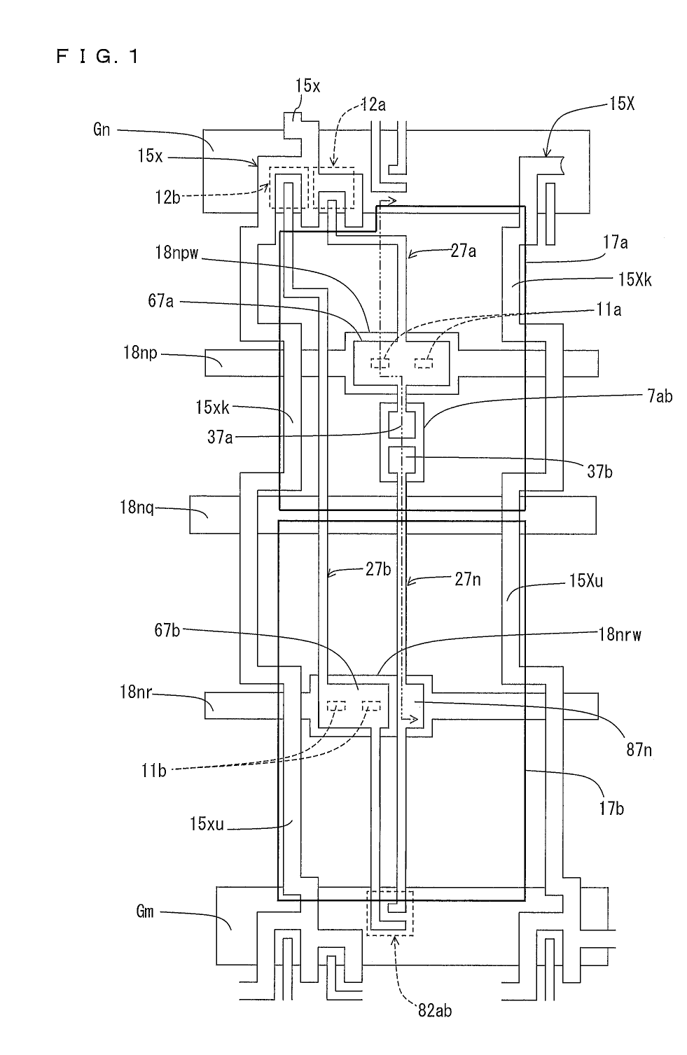

The following description will discuss, with reference to FIGS. 1 through 21, embodiments in accordance with the present invention. For easy explanation, (i) data signal lines extend along a longitudinal (column) direction and (ii) scanning signal lines extend along a lateral (row) direction in the following description. As a matter of course, the scanning signal lines can extend along the lateral direction or along the longitudinal direction in a state where a liquid crystal display device (or a liquid crystal panel or an active matrix substrate which is employed in the liquid crystal display device) of the present invention is used (viewed). Each pixel area in the active matrix substrate corresponds to each pixel in the liquid crystal panel or the liquid crystal display device.

### Embodiment 1

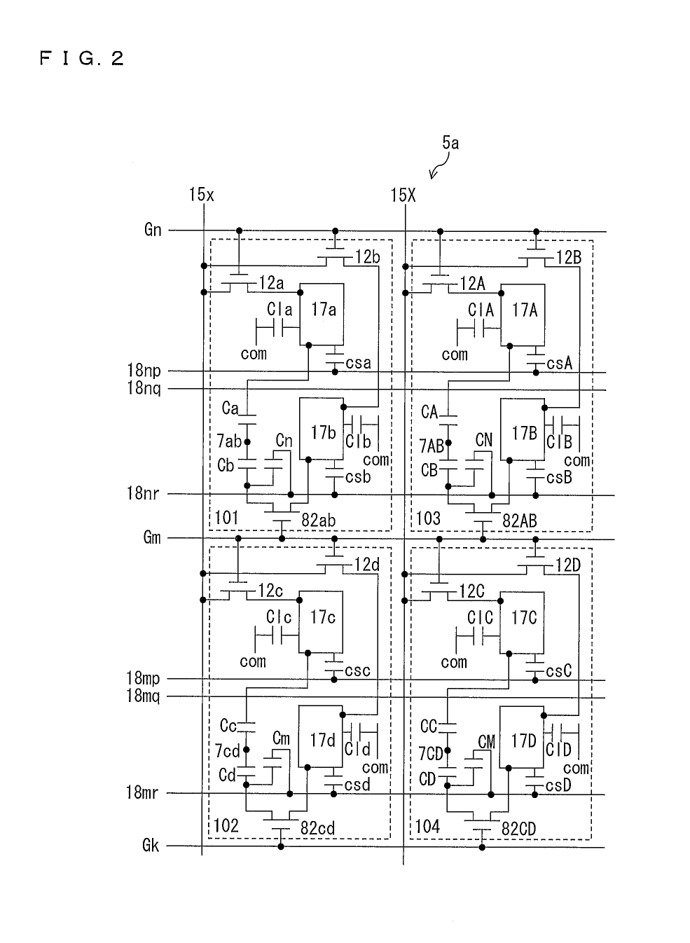

FIG. 2 is an equivalent circuit diagram of part of a liquid crystal panel 5a of the present embodiment. The liquid crystal panel 5a includes: a scanning signal line provided in a row; a data signal line; a first transistor and a second transistor which are connected with the scanning signal line; a third transistor connected with another scanning signal line provided in a next row, wherein (i) a first pixel electrode connected with a drain electrode of the first transistor, (ii) a second pixel electrode connected with a drain electrode of the second transistor, (iii) a first capacitor electrode connected with the first pixel electrode, (iv) a second capacitor electrode connected with the second pixel electrode via the third transistor, and (v) a relay electrode which electrically floats are provided in each pixel area. The first capacitor electrode and the second capacitor electrode are provided in a same layer as the data signal line. The relay electrode is provided in a same layer as the scanning signal lines. A capacitor is formed by the relay electrode and each of the first capacitor electrode and the second capacitor electrode. A capacitor is formed by the second capacitor electrode and retention capacitor wiring.

For example, (i) a data signal line 15x is provided for a pixel column including pixels 101 and 102 which are arranged along the column direction, (ii) a data signal line 15X is provided for a pixel column including pixels 103 and 104 which are arranged along the column direction, (iii) a scanning signal line Gn and three retention capacitor wiring 18np, 18nq, and 18nr are provided for a pixel row including the pixels 101 and 103 which are arranged along the row direction, and (iv) a scanning signal line Gm and three retention capacitor wiring 18mp, 18mq, and 18mr are provided for a pixel row including the pixels 102 and 104 which are arranged along the row direction. Note that the scanning signal line Gn, the scanning signal line Gm, and a scanning signal line Gk are arranged in this order along a scanning direction.

In the pixel 101, (i) two pixel electrodes 17a and 17b are arranged in this order along the column direction, (ii) a source electrode of each of transistors 12a and 12b which are connected with the scanning signal line Gn is connected with the data signal line 15x, (iii) drain electrodes of the transistors 12a and 12b are connected with the pixel electrodes 17a and 17b, respectively, (iv) a source electrode of a transistor 82ab connected with the scanning signal line Gm is connected with the pixel electrode 17b, (v) a drain electrode of the transistor 82ab and a relay electrode 7ab form a capacitor Cb, (vi) the drain electrode of the transistor 82ab and the retention capacitor wiring 18nr form a capacitor Cn, and (vii) the pixel electrode 17a and the relay electrode 7ab form a capacitor Ca. Note that (i) a liquid crystal capacitor C1a is formed by the pixel electrode 17a and a common electrode (counter electrode) com, (ii) a liquid crystal capacitor C1b is formed by the pixel electrode 17b and the common electrode (counter electrode) com, (iii) a retention capacitor csa is formed by the pixel electrode 17a and the retention capacitor wiring 18np, and (iv) a retention capacitor csb is formed by the pixel electrode 17b and the retention capacitor wiring 18nr.

In the pixel 102, which is adjacent to the pixel 101 in the column direction, (i) two pixel electrodes 17c and 17d are arranged in this order along the column direction, (ii) a source electrode of each of transistors 12c and 12d which are connected with the scanning signal line Gm is connected with the data signal line 15x, (iii) drain electrodes of the transistors 12c and 12d are connected with the pixel electrodes 17c and 17d, respectively, (iv) a source electrode of a transistor 82cd connected with the scanning signal line Gk is connected with the pixel electrode 17d, (v) a drain electrode of the transistor 82cd and a relay electrode 7cd form a capacitor Cd, (vi) the drain electrode of the transistor 82cd and the retention capacitor wiring 18mr form a capacitor Cm, and (vii) the pixel electrode 17c and the relay electrode 7cd form a capacitor Cc. Note that (i) a liquid crystal capacitor C1c is formed by the pixel electrode 17c and the common electrode (counter electrode) com, (ii) a liquid crystal capacitor C1d is formed by the pixel electrode 17d and the common electrode (counter electrode) com, (iii) a retention capacitor csc is formed by the pixel electrode 17c and the retention capacitor wiring 18mp, and (iv) a retention capacitor csd is formed by the pixel electrode 17d and the retention capacitor wiring 18mr.

In the pixel 103, which is adjacent to the pixel 101 in the row direction, (i) two pixel electrodes 17A and 17B are arranged in this order along the column direction, (ii) a source electrode of each of transistors 12A and 12B which are connected with the scanning signal line Gn is connected with the data signal line 15X, (iii) drain electrodes of the transistors 12A and 12B are connected with the pixel electrodes 17A and 17B, respectively, (iv) a source electrode of a transistor 82AB connected with the scanning signal line Gm is connected with the pixel electrode 17B, (v) a drain electrode of the transistor 82AB and a relay electrode 7AB form a capacitor CB, (vi) the drain electrode of the transistor 82AB and the retention capacitor wiring 18nr form a capacitor CN, and (vii) the pixel electrode 17A and the relay electrode 7AB form a capacitor CA. Note that (i) a liquid crystal capacitor C1A is formed by the pixel electrode 17A and the common electrode (counter electrode) com, (ii) a liquid crystal capacitor C1B is formed by the pixel electrode 17B and the common electrode (counter electrode) com, (iii) a retention capacitor csA is formed by the pixel electrode 17A and the retention capacitor wiring 18np, and (iv) a retention capacitor csB is formed by the pixel electrode 17B and the retention capacitor wiring 18nr.

In the pixel 104, which is adjacent to the pixel 102 in the row direction, (i) two pixel electrodes 17C and 17D are arranged in this order along the row direction, (ii) a source electrode of each of transistors 12C and 12D which are connected with the scanning signal line Gm is connected with the data signal line 15X, (iii) drain electrodes of the transistors 12C and 12D are connected with the pixel electrodes 17C and 17D, respectively, (iv) a source electrode of a transistor 82CD connected with the scanning signal line Gk is connected with the pixel electrode 17D, (v) a drain electrode of the transistor 82CD and a relay electrode 7CD form a capacitor CD, (vi) the drain electrode of the transistor 82CD and the retention capacitor wiring 18mr form a capacitor CM, and (vii) the pixel electrode 17C and the relay electrode 7CD form a capacitor CC. Note that (i) a liquid crystal capacitor C1C is formed by the pixel electrode 17C and the common electrode (counter electrode) com, (ii) a liquid crystal capacitor C1D is formed by the pixel electrode 17D and the common electrode (counter electrode) com, (iii) a retention capacitor csC is formed by the pixel electrode 17C and the retention capacitor wiring 18mp, and (iv) a retention capacitor csD is formed by the pixel electrode 17D and the retention capacitor wiring 18mr.

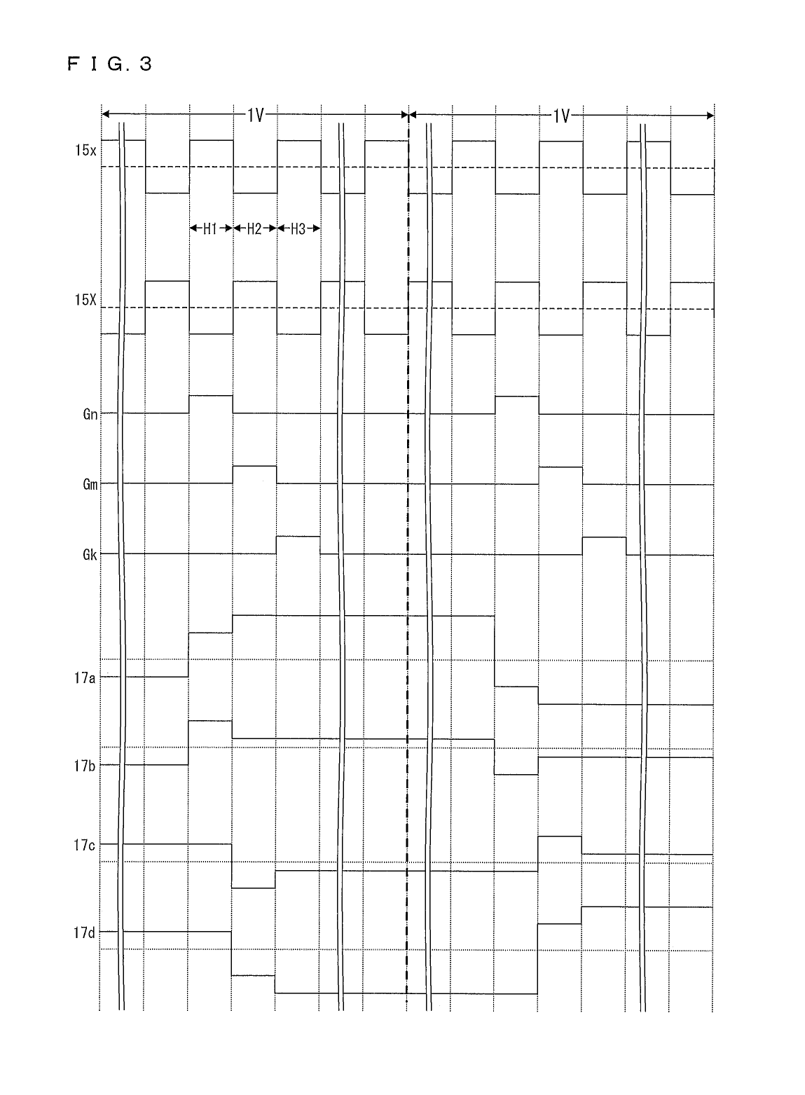

FIG. 3 is a timing chart (2 frames) showing a driving method employed in a case in which halftone solid display is carried out in a part (containing the pixels 101 and 102 illustrated in FIG. 2) of the liquid crystal panel 5a. 15x and 15X in FIG. 3 indicate data signals supplied to the respective data signal lines 15x and 15X illustrated in FIG. 2. Gn, Gm, and Gk in FIG. 3 indicate scanning signals (active High) supplied to the respective scanning signal lines Gn, Gm, and Gk illustrated in FIG. 2. 17a through 17d in FIG. 3 indicate electric potentials of the respective pixel electrodes 17a through 17d illustrated in FIG. 1.

In the driving method shown by FIG. 3, (i) the scanning signal lines are sequentially selected one by one and (ii) data signals having reverse polarities to each other are supplied to respective two adjacent data signal lines (e.g., 15x and 15X). Note that polarities of data signals supplied to respective data signal lines are reversed every horizontal scan period (1H).

For example, during a scan period H1 out of three consecutive horizontal scan periods H1 through H3, the scanning signal line Gn is selected (activated). This causes identical plus data signals to be written into the respective pixel electrodes 17a and 17b as shown in FIG. 3.

Subsequently, during H2, the scanning signal line Gm is selected (activated). The selection of the scanning signal line Gm causes identical minus data signals to be written into the respective pixel electrodes 17c and 17d as shown in FIG. 3. The selection also causes the transistor 82ab (see FIG. 2) to be turned on, so that the pixel electrode 17b (i) is connected with the pixel electrode 17a via the capacitors Ca and Cb (combined capacitance=Ca×Cb/Ca+Cb), which are connected with each other in series and (ii) is connected with the retention capacitor wiring 18nr via the capacitor Cn. This causes the pixel electrode 17b to be discharged. As such, an electric potential of the pixel electrode 17b changes so as to be close to a center electric potential, whereas an electric potential of the pixel electrode 17a changes so as to get away from the center electric potential. As a result, a subpixel corresponding to the pixel electrode 17a becomes a bright subpixel (+) and a subpixel corresponding to the pixel electrode 17b becomes a dark subpixel (+).

Subsequently, during H3, the scanning signal line Gk is selected (activated). This causes the transistor 82cd (see FIG. 2) to be turned on, so that the pixel electrode 17d (i) is connected with the pixel electrode 17c via the capacitors Cc and Cd (combined capacitance=Cc×Cd/Cc+Cd), which are connected with each other in series and (ii) is connected with the retention capacitor wiring 18mr via the capacitor Cm. This causes the pixel electrode 17d to be discharged. As such, an electric potential of the pixel electrode 17d changes so as to be close to the center electric potential, whereas an electric potential of the pixel electrode 17c changes so as to get away from the center electric potential. As a result, a subpixel corresponding to the pixel electrode 17c becomes a bright subpixel (−) and a subpixel corresponding to the pixel electrode 17d becomes a dark subpixel (−).

FIG. 1 is a plan view illustrating an exemplary configuration of one (1) pixel in the liquid crystal panel 5a illustrated in FIG. 2. As illustrated in FIG. 1, in the liquid crystal panel 5a, the pixel electrodes 17a and 17b, each of which has a substantially rectangular shape, are arranged in this order along the column direction in an area defined by the scanning signal line Gn and the data signal line 15x, (ii) the retention capacitor wiring 18np is provided so as to traverse the pixel electrode 17a at the center of the pixel electrode 17a, (iii) the retention capacitor wiring 18nr is provided so as to traverse the pixel electrode 17b at the center of the pixel electrode 17b, and (iv) the retention capacitor wiring 18nq is provided so as to overlap a gap between the pixel electrodes 17a and 17b.

The transistors 12a and 12b are provided near at an intersection of the scanning signal line Gn and the data signal line 15x. The source electrode of the transistor 12a is connected with the data signal line 15x and the drain electrode of the transistor 12a is connected with an extraction (draw-out) electrode 27a. The extraction electrode 27a is provided, below a longitudinal center line of the pixel electrode 17a, so as to be connected with a capacitor electrode 37a provided below the pixel electrode 17a (i.e., the extraction electrode 27a is connected with the capacitor electrode 37a in a same layer as the capacitor electrode 37a). The extraction electrode 27a has an expansive part 67a below a central part of the pixel electrode 17a. The expansive part 67a and the pixel electrode 17a are connected with each other, via two contact holes 11a. The retention capacitor wiring 18np also has a wide part 18npw below the pixel electrode 17a. The expansive part 67a and the wide part 18npw overlap each other via a gate insulating film. Such overlapping causes the capacitor csa (see FIG. 2) to be formed.

The source electrode of the transistor 12b is connected with the data signal line 15x. The drain electrode of the transistor 12b is connected with an extraction electrode 27b. The extraction electrode 27b has an expansive part 67b below the pixel electrode 17b. The expansive part 67b and the pixel electrode 17b are connected with each other, via two contact holes 11b. The retention capacitor wiring 18nr has a wide part 18nrw below the pixel electrode 17b. The expansive part 67b and the wide part 18nrw overlap each other via the gate insulating film. Such overlapping causes the capacitor csb (see FIG. 2) to be formed.

The scanning signal line Gm, which is provided downstream of the scanning signal line Gn in the scanning direction so as to be adjacent to the scanning signal line Gn, is arranged so as to overlap an edge of the pixel electrode 17b which edge is located downstream in the scanning direction. The scanning signal line Gm also functions as a gate electrode of the transistor 82ab. A source electrode of the transistor 82ab is connected with an end part of the extraction electrode 27b. A drain electrode of the transistor 82ab is connected with an extraction electrode 27n. The extraction electrode 27n is provided below a longitudinal center line of the pixel electrode 17b so as to be connected with a capacitor electrode 37b provided below the pixel electrode 17a (i.e., the extraction electrode 27n is connected with the capacitor electrode 37b in a same layer as the capacitor electrode 37b). The extraction electrode 27n has an expansive part 87n below a central part of the pixel electrode 17b. The expansive part 87n and the wide part 18nrw overlap each other via the gate insulating film. Such overlapping causes the capacitor Cn (see FIG. 2) to be formed.

Below the longitudinal center line of the pixel electrode 17a, the relay electrode 7ab is provided, in a form of a floating island, in a same layer as the scanning signal lines and the capacitor wiring. The relay electrode 7ab overlaps each of the capacitor electrodes 37a and 37b, via the gate insulating film. Such overlapping causes each of the capacitors Ca and Cb (see FIG. 2) to be formed.

The data signal line 15x extends so as to meander along the column direction. Parts 15xk and 15xu of the data signal line 15x respectively overlap (i) an edge part which is a lower left part of the pixel electrode 17a in FIG. 1 and (ii) an edge part which is a lower left part of the pixel electrode 17b in FIG. 1. The data signal line 15X also extends so as to meander along the column direction. Parts 15Xk and 15Xu of the data signal line 15X respectively overlap (i) another edge part which is an upper right part of the pixel electrode 17a in FIG. 1 and (ii) another edge part which is an upper right part of the pixel electrode 17b in FIG. 1.

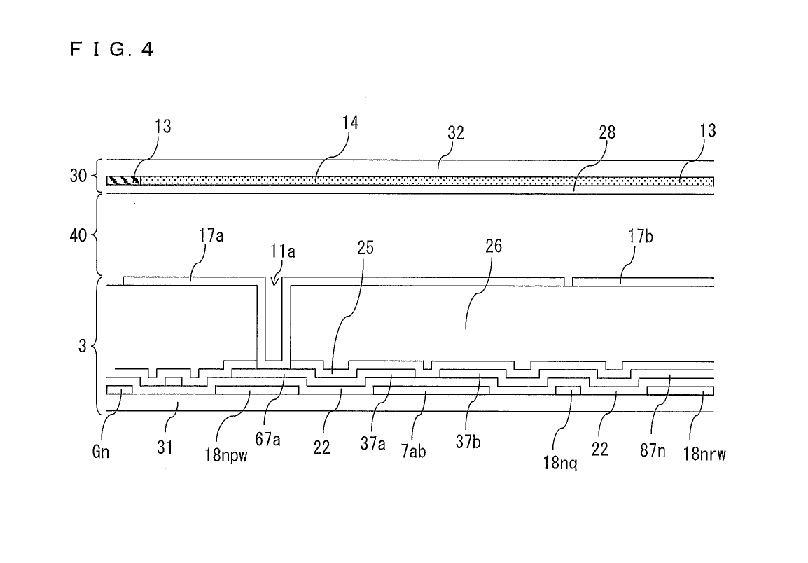

FIG. 4 is a cross-sectional view taken along a line indicated by arrows of FIG. 1. As illustrated in FIG. 4, the liquid crystal panel 5a includes (i) an active matrix substrate 3, (ii) a color filter substrate 30 facing the active matrix substrate 3, and (iii) a liquid crystal layer 40 provided between both of the substrates (3 and 30).

In the color filter substrate 30, (i) a black matrix and a colored layer 14 are provided on a glass substrate 32 and (ii) a common electrode (com) 28 is provided on the black matrix 13 and the colored layer 14. Note that the liquid crystal layer 30 is constituted by liquid crystal of, for example, an optical alignment mode (4 domains) which has been subjected to an alignment treatment by means of ultraviolet ray.

In the active matrix substrate 3, (i) the scanning signal line Gn, the relay electrode lab, and the retention capacitor wiring 18np (18npw), 18nq, and 18nr (18nrw) are provided on a glass substrate 31 and (ii) a gate insulating film 22 which, for example, has a thickness of 200 nm and made from SiNx is provided so as to cover the scanning signal line Gn, the relay electrode lab, and the retention capacitor wiring 18np (18npw), 18nq, and 18nr (18nrw). On the gate insulating film 22, (i) semiconductor layers (i-layer and n+ layer), (ii) a source electrode and a drain electrode which are in contact with the n+ layer, (iii) the extraction electrode 27a (expansive part 67a), (iv) the capacitor electrodes 37a and 37b, and (v) the extraction electrode 27n (expansive part 87n) are formed by use of, for example, Ti and Al (the semiconductor layers, the source electrode, and the drain electrode are not included in the cross-section and are therefore not shown in FIG. 4). An inorganic interlayer insulating film 25 made from, for example, SiNx is provided so as to cover the semiconductor layers, the source electrode, the drain electrode, the extraction electrode 27a (expansive part 67a), the capacitor electrodes 37a and 37b, and the extraction electrode 27n (expansive part 87n). An organic interlayer insulating film 26 with a thickness (about 2μ) larger than that of the inorganic interlayer insulating film 25 is provided on the inorganic interlayer insulating film 25. The pixel electrodes 17a and 17b are provided on the organic interlayer insulating film 26. Each of the contact holes 11a is formed by hollowing out the inorganic interlayer insulating film 25 and the organic interlayer insulating film 26. This causes the pixel electrode 17a and the expansive part 67a (of the extraction electrode 27a) to be connected with each other.

The formation of the capacitor csa (see FIG. 2) is caused by the overlapping, merely via the gate insulating film 22, of the expansive part 67a and the wide part 18npw (of the retention capacitor wiring 18np).

The formation of the capacitor Ca (see FIG. 2) is caused by the overlapping, merely via the gate insulating film 22, of (i) the capacitor electrode 37a and (ii) the relay electrode 7ab which is provided in a same layer as the scanning signal line Gn. The formation of the capacitor Cb (see FIG. 2) is caused by the overlapping, merely via the gate insulating film 22, of the capacitor electrode 37b and the relay electrode 7ab. The formation of the capacitor Cn (see FIG. 2) is caused by the overlapping, merely via the gate insulating film 22, of the expansive part 87n (of the extraction electrode 27n) and the wide part 18nrw (of the retention capacitor wiring 18nr).

According to the liquid crystal panel of the present embodiment, it is thus possible to (i) provide the organic interlayer insulating film 26 with a large thickness and (ii) secure sufficiently large capacitances of the respective capacitors Ca, Cb and Cn. It accordingly becomes possible to have a high-aperture-ratio structure in which edges of the pixel electrodes 17a and 17b overlap the data signal lines 15x and 15X and the scanning signal lines Gn and Gm.

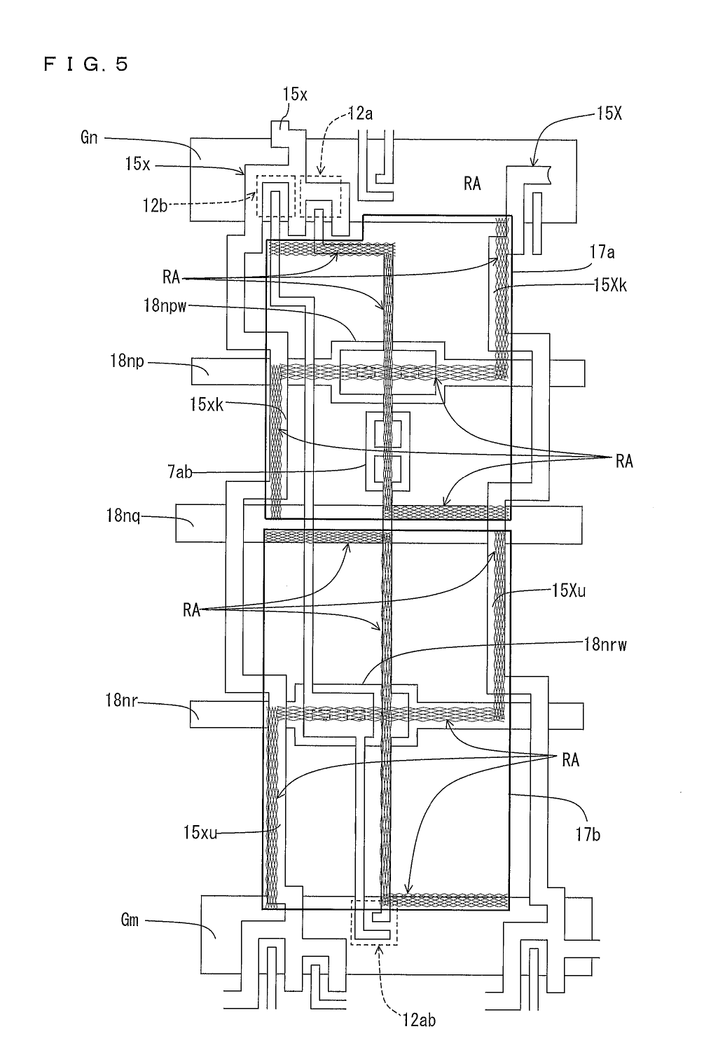

Below each of the pixel electrodes, (i) corresponding ones of the retention capacitor wiring and (ii) a corresponding one(s) of the extraction electrodes (and corresponding ones of the capacitor electrodes) crisscross, and each of the data signal lines meanders so as to overlap edges of the pixel electrodes. This configuration allows swastika-shaped disclination (irregular orientation) areas, which are observed in a case of using liquid crystal of an optical alignment mode, to be hidden (see FIG. 5).

In addition, since the liquid crystal panel 5a employs the 3-transistor capacitive coupling type pixel division system, the liquid crystal panel 5a (i) has a good viewing angle characteristic and (ii) is more reliable than a liquid crystal panel of the 1-transistor capacitive coupling type because of having no pixel electrode that electrically floats.

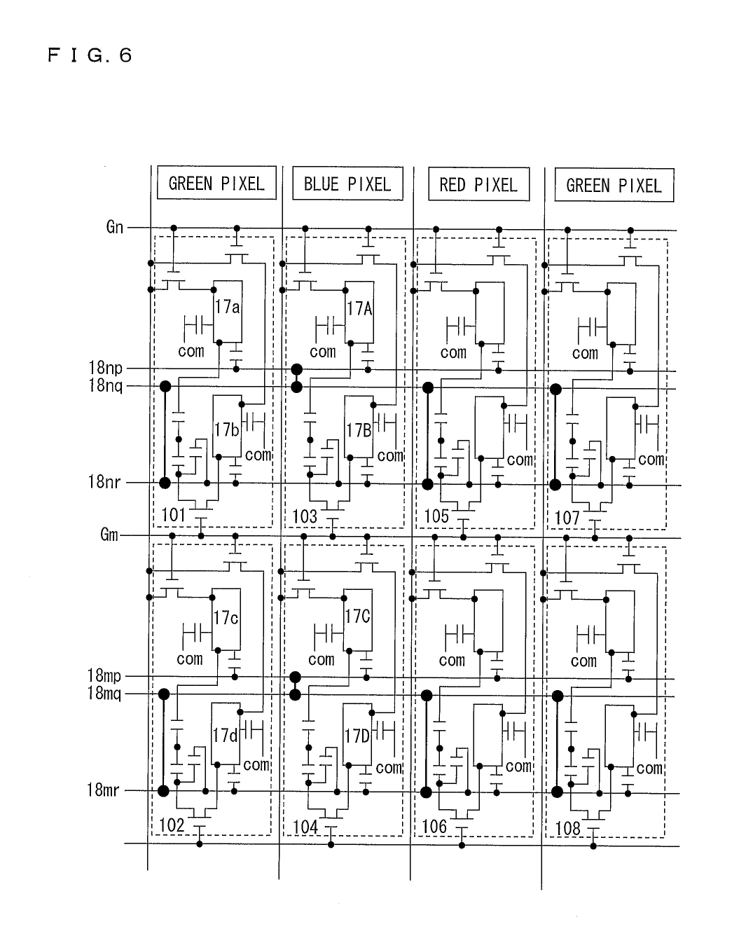

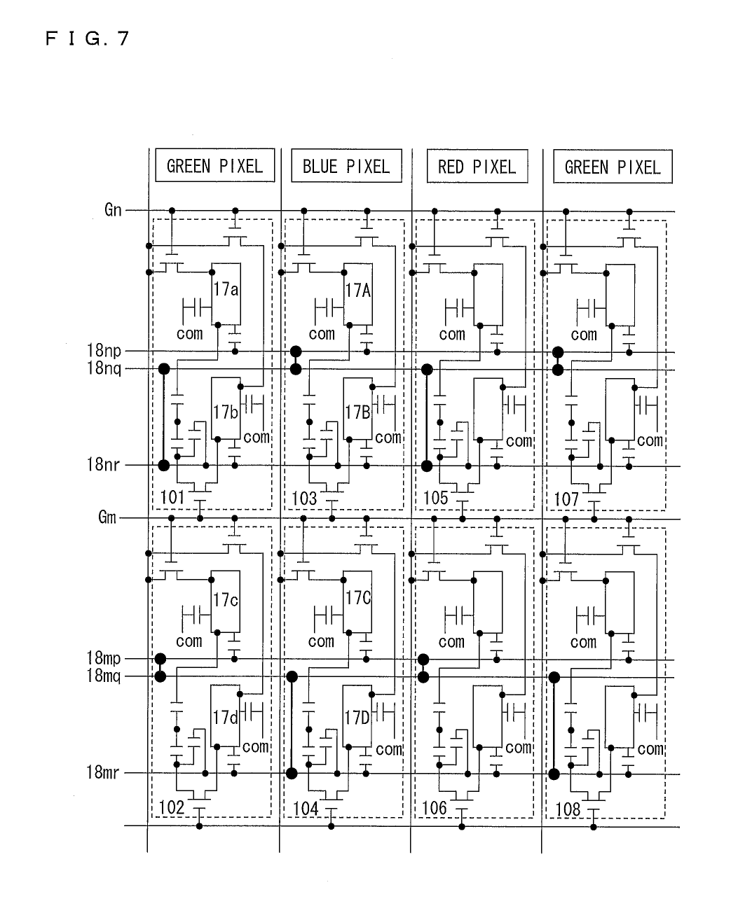

Note that the liquid crystal panel 5a illustrated in FIG. 2 can be modified so as to provide a liquid crystal panel with a configuration illustrated in FIG. 6. In the configuration illustrated in FIG. 6, (i) the retention capacitor wiring 18nq and the retention capacitor wiring 18nr are connected with each other in a green pixel and a red pixel and (ii) the retention capacitor wiring 18np and the retention capacitor wiring 18nq are connected with each other in a blue pixel. Alternatively, the liquid crystal panel 5a illustrated in FIG. 2 can be modified so as to provide a liquid crystal panel with a configuration illustrated in FIG. 7. In the configuration illustrated in FIG. 7, (i) the retention capacitor wiring 18nq and the retention capacitor wiring 18nr are connected with each other in one of two pixels that are adjacent to each other in the row direction, (ii) the retention capacitor wiring 18np and the retention capacitor wiring 18nq are connected with each other in the other of the two pixels adjacent to each other in the row direction, (iii) the retention capacitor wiring 18nq and the retention capacitor wiring 18nr are connected with each other in one of two pixels that are adjacent to each other in the column direction, and (iv) the retention capacitor wiring 18np and the retention capacitor wiring 18nq are connected with each other in the other of the two pixels adjacent to each other in the column direction. According to the configurations illustrated in FIGS. 6 and 7, a range of changes in electric potential of each retention capacitor wiring can be reduced and display unevenness can be prevented accordingly.

### Embodiment 2

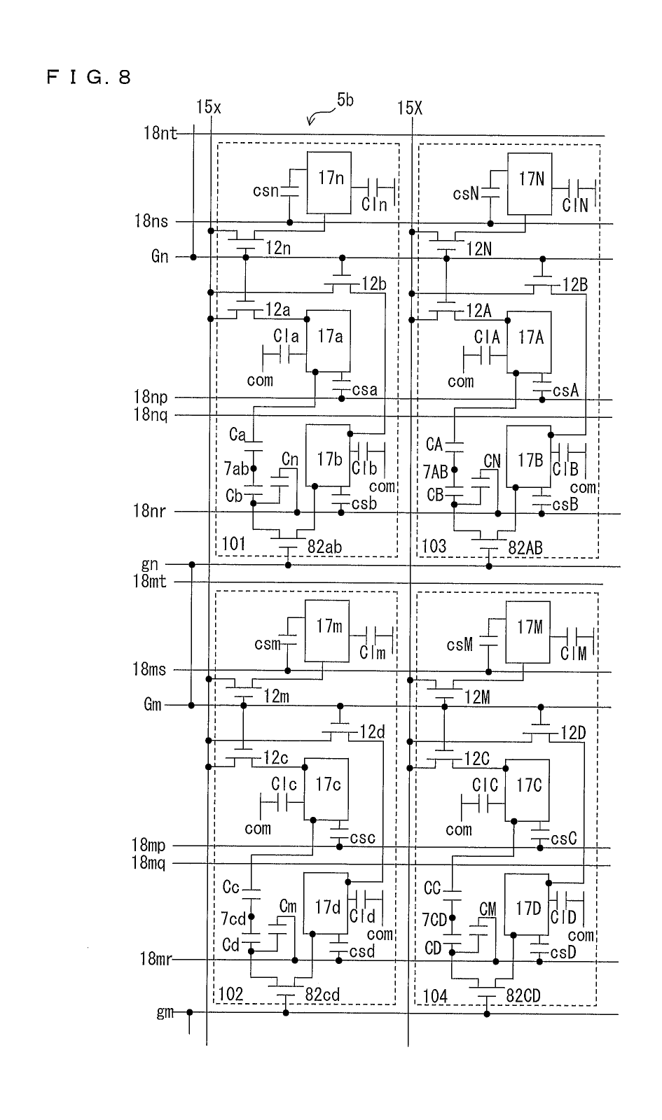

FIG. 8 is an equivalent circuit diagram of part of a liquid crystal panel 5b of the present embodiment. The liquid crystal panel 5b includes: a scanning signal line provided in a row; a data signal line; a first transistor and a second transistor which are connected with the scanning signal line; a third transistor connected with another scanning signal line provided in a next row; and a fourth transistor connected with the scanning signal line, wherein (i) a first pixel electrode connected with a drain electrode of the first transistor, (ii) a second pixel electrode connected with a drain electrode of the second transistor, (iii) a third pixel electrode connected with a drain electrode of the fourth transistor, (iv) a first capacitor electrode connected with the first pixel electrode, (v) a second capacitor electrode connected with the second pixel electrode via the third transistor, and (iv) a relay electrode which electrically floats are provided in each pixel area. The first capacitor electrode and the second capacitor electrode are provided in a same layer as the data signal line. The relay electrode is provided in a same layer as the scanning signal lines. A capacitor is formed by the relay electrode and each of the first capacitor electrode and the second capacitor electrode. A capacitor is formed by the second capacitor electrode and retention capacitor wiring.

For example, (i) a data signal line 15x is provided for a pixel column including pixels 101 and 102 which are arranged along the column direction, (ii) a data signal line 15X is provided for a pixel column including pixels 103 and 104 which are arranged along the column direction, (iii) two scanning signal lines Gn and gn and five retention capacitor wiring 18np, 18nq, 18nr, 18ns, and 18nt are provided for a pixel row including the pixels 101 and 103 which are arranged along the row direction, and (iv) two scanning signal lines Gm and gm and five retention capacitor wiring 18mp, 18mq, 18mr, 18ms, and 18mt are provided for a pixel row including the pixels 102 and 104 which are arranged along the row direction. Note that the scanning signal lines Gn, gn, Gm, and gm are arranged in this order along the scanning direction.

In the pixel 101, (i) three pixel electrodes 17n, 17a, and 17b are arranged in this order along the column direction, (ii) a source electrode of each of transistors 12a, 12b, and 12n connected with the scanning signal line Gn is connected with the data signal line 15x, (iii) drain electrodes of the transistors 12a, 12b, and 12n are connected with the pixel electrodes 17n, 17a, and 17b, respectively, (iv) a source electrode of a transistor 82ab connected with the scanning signal line gn is connected with the pixel electrode 17b, (v) a drain electrode of the transistor 82ab and a relay electrode 7ab form a capacitor Cb, (vi) the drain electrode of the transistor 82ab and the retention capacitor wiring 18nr form a capacitor Cn, and (vii) the pixel electrode 17a and the relay electrode 7ab form a capacitor Ca. Note that (i) a liquid crystal capacitor C1a is formed by the pixel electrode 17a and a common electrode (counter electrode) com, (ii) a liquid crystal capacitor C1b is formed by the pixel electrode 17b and the common electrode (counter electrode) com, (iii) a liquid crystal capacitor C1n is formed by the pixel electrode 17n and the common electrode (counter electrode) com, (iv) a retention capacitor csa is formed by the pixel electrode 17a and the retention capacitor wiring 18np, (v) a retention capacitor csb is formed by the pixel electrode 17b and the retention capacitor wiring 18nr, and (vi) a retention capacitor can is formed by the pixel electrode 17n and the retention capacitor wiring 18ns.

In the pixel 102, which is adjacent to the pixel 101 in the column direction, (i) two pixel electrodes 17m, 17c, and 17d are arranged in this order along the column direction, (ii) a source electrode of each of transistors 12c, 12d, and 12m connected with the scanning signal line Gm is connected with the data signal line 15x, (iii) drain electrodes of the transistors 12c, 12d, and 12m are connected with the pixel electrodes 17c, 17d, and 17m, respectively, (iv) a source electrode of a transistor 82cd connected with the scanning signal line gm is connected with the pixel electrode 17d, (v) a drain electrode of the transistor 82cd and a relay electrode 7cd form a capacitor Cd, (vi) the drain electrode of the transistor 82cd and the retention capacitor wiring 18mr form a capacitor Cm, and (vii) the pixel electrode 17c and the relay electrode 7cd form a capacitor Cc. Note that (i) a liquid crystal capacitor C1c is formed by the pixel electrode 17c and the common electrode (counter electrode) com, (ii) a liquid crystal capacitor C1d is formed by the pixel electrode 17d and the common electrode (counter electrode) com, (iii) a liquid crystal capacitor C1m is formed by the pixel electrode 17m and the common electrode (counter electrode) com, (iv) a retention capacitor csc is formed by the pixel electrode 17c and the retention capacitor wiring 18mp, (v) a retention capacitor csd is formed by the pixel electrode 17d and the retention capacitor wiring 18mr, and (vi) a retention capacitor csm is formed by the pixel electrode 17m and the retention capacitor wiring 18ms.

In the pixel 103, which is adjacent to the pixel 101 in the row direction, (i) two pixel electrodes 17N, 17A, and 17B are arranged in this order along the column direction, (ii) a source electrode of each of transistors 12A, 12B, and 12N connected with the scanning signal line Gn is connected with the data signal line 15X, (iii) drain electrodes of the transistors 12A, 12B, and 12N are connected with the pixel electrodes 17A, 17B, and 17N, respectively, (iv) a source electrode of a transistor 82AB connected with the scanning signal line gn is connected with the pixel electrode 17B, (v) a drain electrode of the transistor 82AB and a relay electrode 7AB form a capacitor CB, (vi) the drain electrode of the transistor 82AB and the retention capacitor wiring 18nr form a capacitor CN, and (vii) the pixel electrode 17A and the relay electrode 7AB form a capacitor CA. Note that (i) a liquid crystal capacitor C1A is formed by the pixel electrode 17A and the common electrode (counter electrode) com, (ii) a liquid crystal capacitor C1B is formed by the pixel electrode 17B and the common electrode (counter electrode) com, (iii) a liquid crystal capacitor C1N is formed by the pixel electrode 17N and the common electrode (counter electrode) com, (iv) a retention capacitor csA is formed by the pixel electrode 17A and the retention capacitor wiring 18np, (v) a retention capacitor csB is formed by the pixel electrode 17B and the retention capacitor wiring 18nr, and (vi) a retention capacitor csN is formed by the pixel electrode 17N and the retention capacitor wiring 18ns.

In the pixel 104, which is adjacent to the pixel 102 in the row direction, (i) three pixel electrodes 17M, 17C, and 17D are arranged in this order along the column direction, (ii) a source electrode of each of transistors 12C, 12D, and 12M connected with the scanning signal line Gm is connected with the data signal line 15X, (iii) drain electrodes of the transistors 12C, 12D, and 12M are connected with the pixel electrodes 17C, 17D, and 17M, respectively, (iv) a source electrode of a transistor 82CD connected with the scanning signal line gm is connected with the pixel electrode 17D, (v) a drain electrode of the transistor 82CD and a relay electrode 7CD form a capacitor CD, (vi) the drain electrode of the transistor 82CD and the retention capacitor wiring 18mr form a capacitor CM, and (vii) the pixel electrode 17C and the relay electrode 7CD form a capacitor CC. Note that (i) a liquid crystal capacitor C1C is formed by the pixel electrode 17C and the common electrode (counter electrode) com, (ii) a liquid crystal capacitor C1D is formed by the pixel electrode 17D and the common electrode (counter electrode) com, (iii) a liquid crystal capacitor C1M is formed by the pixel electrode 17M and the common electrode (counter electrode) com, (iv) a retention capacitor csC is formed by the pixel electrode 17C and the retention capacitor wiring 18mp, (v) a retention capacitor csD is formed by the pixel electrode 17D and the retention capacitor wiring 18mr, and (vi) a retention capacitor csM is formed by the pixel electrode 17M and the retention capacitor wiring 18ms.

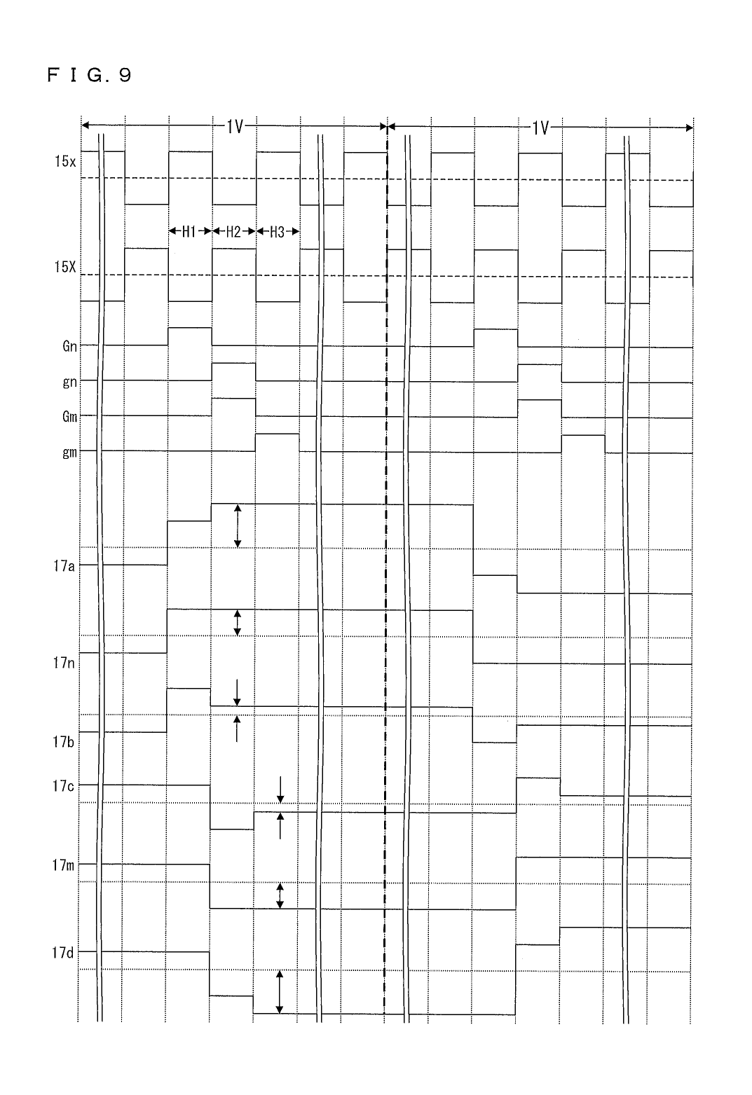

FIG. 9 is a timing chart (2 frames) showing a driving method employed in a case in which halftone solid display is carried out in a part (containing the pixels 101 and 102 illustrated in FIG. 2) of the liquid crystal panel 5b. 15x and 15X in FIG. 9 indicate data signals supplied to the respective data signal lines 15x and 15X illustrated in FIG. 8. Gn, gn, Gm, and gm in FIG. 9 indicate scanning signals (active High) supplied to the respective scanning signal lines Gn, gn, Gm, and gm illustrated in FIG. 8. 17a through 17d in FIG. 9 indicate electric potentials of the respective pixel electrodes 17a through 17d illustrated in FIG. 8.

In the driving method shown by FIG. 9, (i) the scanning signal lines are sequentially selected two by two and (ii) data signals having reverse polarities to each other are supplied to respective two adjacent data signal lines (e.g., 15x and 15X). Note that polarities of data signals supplied to respective data signal lines are reversed every horizontal scan period (1H).

For example, during a horizontal scan period H1 out of three consecutive horizontal scan periods H1 through H3, the scanning signal line Gn and a scanning signal line upstream of the scanning signal line Gn are selected (activated). This causes identical plus data signals to be written into the respective pixel electrodes 17a, 17b, and 17n as shown in FIG. 9.

Subsequently, during H2, the scanning signal line gn and the scanning signal line Gm are selected (activated). The selection of the scanning signal line gn and the scanning signal line Gm causes identical minus data signals to be written into the respective pixel electrodes 17c, 17d, and 17m as shown in FIG. 9. The selection also causes the transistor 82ab (see FIG. 8) to be turned on, so that the pixel electrode 17b (i) is connected with the pixel electrode 17a via the capacitors Ca and Cb (combined capacitance=Ca×Cb/Ca+Cb), which are connected with each other in series and (ii) is connected with the retention capacitor wiring 18nr via the capacitor Cn. This causes the pixel electrode 17b to be discharged. As such, an electric potential of the pixel electrode 17b changes so as to be close to a center electric potential, whereas an electric potential of the pixel electrode 17a changes so as to get away from the center electric potential. In contrast, the pixel electrode 17n holds the electric potential and the data signal which has been written into the pixel electrode 17n. As a result, (i) a subpixel corresponding to the pixel electrode 17a becomes a bright subpixel (+), (ii) a subpixel corresponding to the pixel electrode 17b becomes a dark subpixel (+), and (iii) a subpixel corresponding to the pixel electrode 17n becomes a subpixel (medium subpixel) which is darker than the bright subpixel and brighter than the dark subpixel.

Subsequently, during H3, the scanning signal line gm and a scanning signal line downstream of the scanning signal line gm are selected (activated). This causes the transistor 82cd (see FIG. 8) to be turned on, so that the pixel electrode 17d (i) is connected with the pixel electrode 17c via the capacitors Cc and Cd (combined capacitance=Cc×Cd/Cc+Cd), which are connected with each other in series and (ii) is connected with the retention capacitor wiring 18mr via the capacitor Cm. This causes the pixel electrode 17d to be discharged. As such, an electric potential of the pixel electrode 17d changes so as to be close to the center electric potential, whereas an electric potential of the pixel electrode 17c changes so as to get away from the center electric potential. In contrast, the pixel electrode 17m holds the electric potential and the minus data signal which has been written into the pixel electrode 17m. As a result, (i) a subpixel corresponding to the pixel electrode 17c becomes a bright subpixel (−), (ii) a subpixel corresponding to the pixel electrode 17d becomes a dark subpixel (−), and (iii) a subpixel corresponding to the pixel electrode 17m becomes a medium subpixel (−).

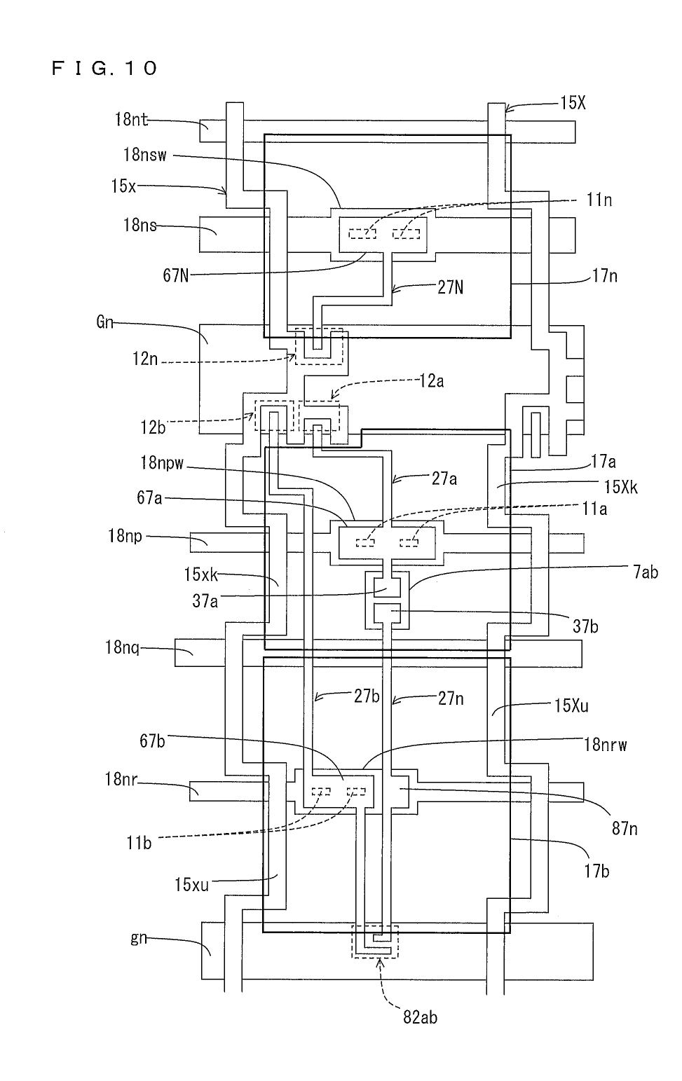

FIG. 10 is a plan view illustrating an exemplary configuration of one (1) pixel in the liquid crystal panel 5b illustrated in FIG. 8. As illustrated in FIG. 10, in the liquid crystal panel 5b, (i) the pixel electrodes 17a and 17b, each of which has a substantially rectangular shape, are arranged in this order along the column direction in an area defined by the scanning signal line Gn and the data signal line 15x and (ii) the pixel electrode 17n is provided upstream of the pixel electrode 17a in the scanning direction. The retention capacitor wiring 18np is provided so as to traverse the pixel electrode 17a at a center of the pixel electrode 17a. The retention capacitor wiring 18nr is provided so as to traverse the pixel electrode 17b at a center of the pixel electrode 17b. The retention capacitor wiring 18nq is provided so as to overlap a gap between the pixel electrodes 17a and 17b. The retention capacitor wiring 18ns is provided so as to traverse the pixel electrode 17n at a center of the pixel electrode 17n. The retention capacitor wiring 18nt is provided so as to overlap an edge of the pixel electrode 17n which edge is located upstream in the scanning direction.

The scanning signal line Gn is arranged so as to overlap a gap between the pixel electrode 17n and the pixel electrode 17a. The transistors 12a, 12b, and 12n are provided near at an intersection of the scanning signal line Gn and the data signal line 15x.

The source electrode of the transistor 12n is connected with the data signal line 15x. The drain electrode of the transistor 12n is connected with an extraction (draw-out) electrode 27N. The extraction electrode 27N has an expansive part 67n below a central part of the pixel electrode 17n. The expansive part 67n and the pixel electrode 17n are connected with each other, via two contact holes 11n. The retention capacitor wiring 18ns also has a wide part 18nsw below the pixel electrode 17n. The expansive part 67n and the wide part 18nsw overlap each other via a gate insulating film. Such overlapping causes the capacitor can (see FIG. 8) to be formed.

The source electrode of the transistor 12a is connected with the data signal line 15x. The drain electrode of the transistor 12a is connected with an extraction electrode 27a. The extraction electrode 27a is provided below a longitudinal center line of the pixel electrode 17a so as to be connected with a capacitor electrode 37a provided below the pixel electrode 17a (i.e., the extraction electrode 27a is connected with the capacitor electrode 37a in a same layer as the capacitor electrode 37a). The extraction electrode 27a has an expansive part 67a below a central part of the pixel electrode 17a. The expansive part 67a and the pixel electrode 17a are connected with each other via two contact holes 11a. The retention capacitor wiring 18np has a wide part 18npw below the pixel electrode 17a. The expansive part 67a and the wide part 18npw overlap each other via the gate insulating film. Such overlapping causes the capacitor csa (see FIG. 8) to be formed.

The source electrode of the transistor 12b is connected with the data signal line 15x. The drain electrode of the transistor 12b is connected with an extraction electrode 27b. The extraction electrode 27b has an expansive part 67b below the pixel electrode 17b. The expansive part 67b and the pixel electrode 17b are connected with each other, via two contact holes 11b. The retention capacitor wiring 18nr has a wide part 18nrw below the pixel electrode 17b. The expansive part 67b and the wide part 18nrw overlap each other via the gate insulating film. Such overlapping causes the capacitor csb (see FIG. 8) to be formed.

The scanning signal line gn, which is provided downstream of the scanning signal line Gn in the scanning direction so as to be adjacent to the scanning signal line, is arranged so as to overlap an edge of the pixel electrode 17b which edge is located downstream in the scanning direction. The scanning signal line gn also functions as the gate electrode of the transistor 82ab. A source electrode of the transistor 82ab is connected with an end part of the extraction electrode 27b. A drain electrode of the transistor 82ab is connected with an extraction electrode 27n. The extraction electrode 27n is provided below a longitudinal center line of the pixel electrode 17b so as to be connected with the capacitor electrode 37b provided below the pixel electrode 17a (i.e., the extraction electrode 27n is connected with the capacitor electrode 37b in a same layer as the capacitor electrode 37b). The extraction electrode 27n has an expansive part 87n below a central part of the pixel electrode 17b. The expansive part 87n and the wide part 18nrw overlap each other via the gate insulating film. Such overlapping causes the capacitor Cn (see FIG. 8) to be formed. Note that the extraction electrode 27n and the capacitor electrode 37b constitute a coupling electrode.

Below the longitudinal center line of the pixel electrode 17a, the relay electrode 7ab is provided, in a form of a floating island, in a same layer as the scanning signal lines and the capacitor wiring. The relay electrode 7ab and the capacitor electrode 37a overlap each other, via the gate insulating film. Such overlapping causes the capacitor Ca (see FIG. 8) to be formed. The relay electrode 7ab and the capacitor electrode 37b overlap each other, via the gate insulating film. Such overlapping causes the capacitor Cb (see FIG. 8) to be formed.

The data signal line 15x extends so as to meander along the column direction. Parts 15xk, 15xu, and 15xv of the data signal line 15x respectively overlap (i) an edge part which is a lower left part of the pixel electrode 17a in FIG. 10, (ii) an edge part which is a lower left part of the pixel electrode 17b in FIG. 10, and (iii) an edge part which is a lower left part of the pixel electrode 17n in FIG. 10. The data signal line 15X also extends so as to meander along the column direction. Parts 15Xk, 15Xu, and 15XV of the data signal line 15X respectively overlap (i) another edge part which is an upper right part of the pixel electrode 17a in FIG. 10, (ii) another edge part which is an upper right part of the pixel electrode 17b in FIG. 10, and (iii) another edge part which is an upper right part of the pixel electrode 17n in FIG. 10.

A cross-sectional view of FIG. 10 is shown in FIG. 4. As illustrated in FIG. 4, the liquid crystal panel 5b includes (i) an active matrix substrate 3, (ii) a color filter substrate 30 facing the active matrix substrate 3, and (ii) a liquid crystal layer 40 provided between both of the substrates (3 and 30).

In the color filter substrate 30, (i) a black matrix and a colored layer 14 are provided on a glass substrate 32 and (ii) a common electrode (com) 28 is provided on the black matrix 13 and the colored layer 14. Note that the liquid crystal layer 30 is constituted by liquid crystal of, for example, an optical alignment mode (4 domains) which has been subjected to an alignment treatment by means of ultraviolet ray.

In the active matrix substrate 3, (i) the scanning signal line Gn, the relay electrode 7ab, and the retention capacitor wiring 18np (18npw), 18nq, and 18nr (18nrw) are provided on a glass substrate 31 and (ii) a gate insulating film 22 which, for example, has a thickness of 200 nm and made from SiNx is provided so as to cover the scanning signal line Gn, the relay electrode 7ab, and the retention capacitor wiring 18np (18npw), 18nq, and 18nr (18nrw). On the gate insulating film 22, (i) semiconductor layers (i-layer and n+ layer), (ii) a source electrode and a drain electrode which are in contact with the n+ layer, (iii) the extraction electrode 27a (expansive part 67a), (iv) the capacitor electrodes 37a and 37b, and (v) the extraction electrode 27n (expansive part 87n) are formed by, for example, Ti and Al (the semiconductor layers, the source electrode, and the drain electrode are not included in the cross-section and are therefore not shown in FIG. 4). An inorganic interlayer insulating film 25 made from, for example, SiNx is provided so as to cover the semiconductor layers (i-layer and n+ layer), the source electrode, the drain electrode, the extraction electrode 27a (expansive part 67a), the capacitor electrodes 37a and 37b, and the extraction electrode 27n (expansive part 87n). An organic interlayer insulating film 26 with a thickness (about 2μ) larger than that of the inorganic interlayer insulating film 25 is provided on the inorganic interlayer insulating film 25. The pixel electrodes 17a and 17b are provided on the organic interlayer insulating film 26. Each of the contact holes 11a is formed by hollowing out the inorganic interlayer insulating film 25 and the organic interlayer insulating film 26. This causes the pixel electrode 17a and the expansive part 67a (of the extraction electrode 27a) to be connected with each other.

The formation of the capacitor csa (see FIG. 8) is caused by the overlapping, merely via the gate insulating film 22, of the expansive part 67a and the wide part 18npw (of the retention capacitor wiring 18np).

The formation of the capacitor Ca (see FIG. 8) is caused by the overlapping, merely via the gate insulating film 22, of (i) the capacitor electrode 37a and (ii) the relay electrode 7ab which is provided in a same layer as the scanning signal line Gn. The formation of the capacitor Cb (see FIG. 8) is caused by the overlapping, merely via the gate insulating film 22, of the capacitor electrode 37b and the relay electrode 7ab. The formation of the capacitor Cn (see FIG. 8) is caused by the overlapping, merely via the gate insulating film 22, of the expansive part 87n (of the extraction electrode 27n) and the wide part 18nrw (of the retention capacitor wiring 18nr).

According to the liquid crystal panel of the present embodiment, it is thus possible to (i) provide the organic interlayer insulating film 26 with a large thickness and (ii) secure sufficiently large capacitances of the respective capacitors Ca, Cb and Cn. It accordingly becomes possible to have a high-aperture-ratio structure in which edges of the pixel electrodes 17a and 17b overlap the data signal lines 15x and 15X and the scanning signal lines Gn and gm.

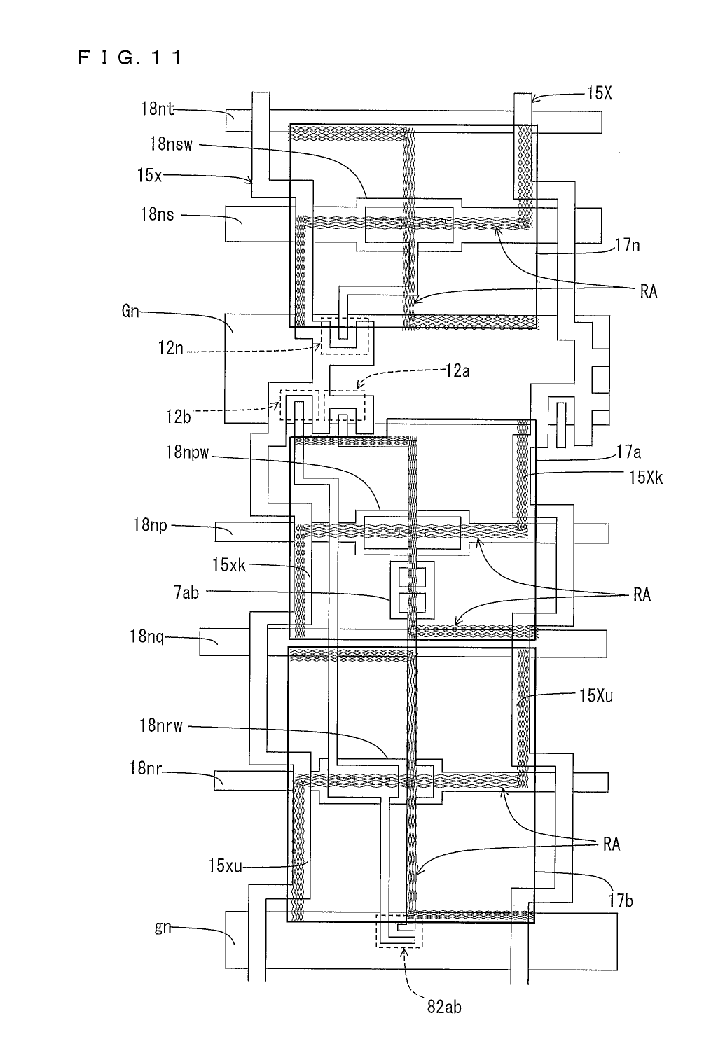

Below each of the pixel electrodes, (i) a corresponding one(s) of the retention capacitor wiring and (ii) a corresponding one(s) of the extraction electrodes (and corresponding ones of the capacitor electrodes) crisscross, and each of the data signal lines meanders so as to overlap edges of the pixel electrodes. This configuration allows swastika-shaped disclination (irregular orientation) areas, which are observed in a case of using liquid crystal of an optical alignment mode, to be hidden (see FIG. 11).

The liquid crystal panel 5b is capable of displaying a halftone by means of subpixels with respective three levels of luminance (three types of VT curves): bright, dark, and medium. This allows a further improvement in viewing angle characteristic of the liquid crystal panel 5b. In addition, the liquid crystal panel 5b is more reliable than a liquid crystal panel of the 1-transistor capacitive coupling type because of having no pixel electrode that electrically floats.

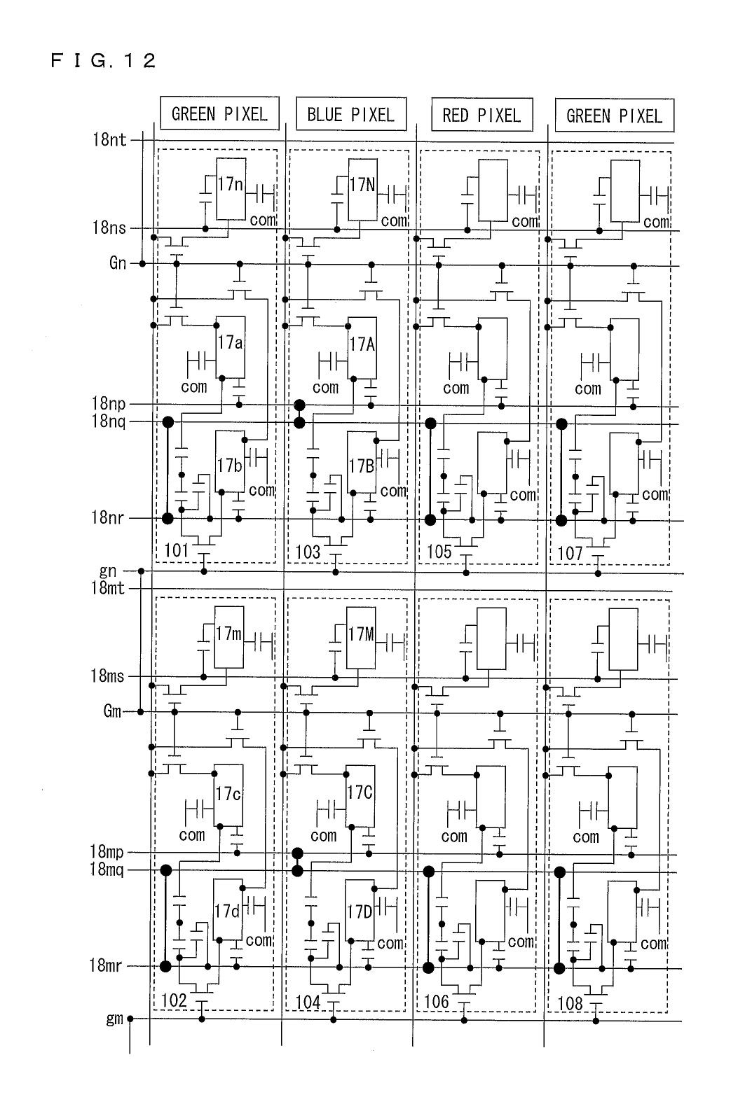

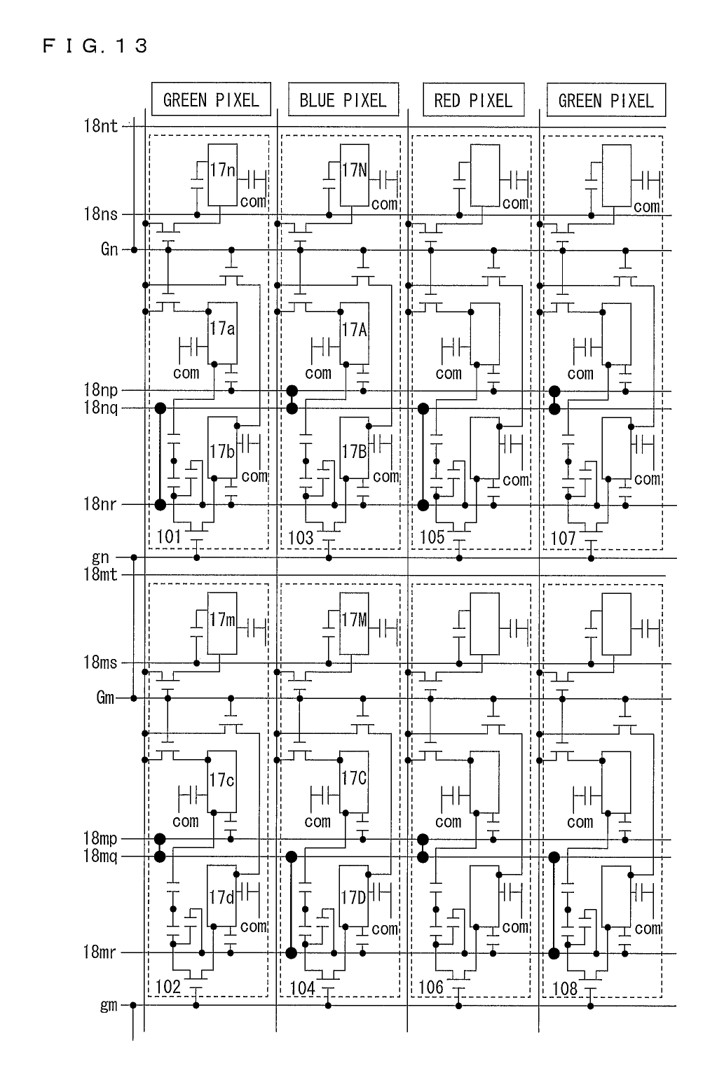

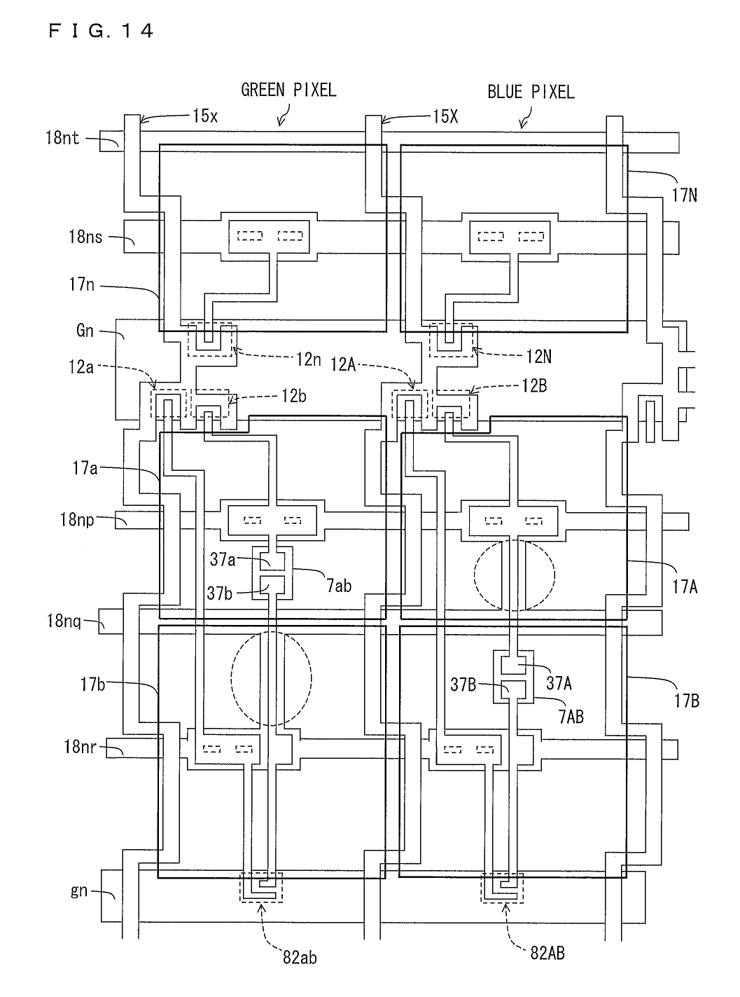

Note that the liquid crystal panel 5b illustrated in FIG. 8 can be modified so as to provide a liquid crystal panel with a configuration illustrated in FIG. 12. In the configuration, (i) the retention capacitor wiring 18nq and the retention capacitor wiring 18nr are connected with each other in a green pixel and a red pixel (i) the retention capacitor wiring 18np and the retention capacitor wiring 18nq are connected with each other in a blue pixel. Alternatively, the liquid crystal panel 5a illustrated in FIG. 8 can be modified so as to provide a liquid crystal panel with a configuration illustrated in FIG. 13. In the configuration, (i) the retention capacitor wiring 18nq and the retention capacitor wiring 18nr are connected with each other in one of two pixels that are adjacent to each other in the row direction, (ii) the retention capacitor wiring 18np and the retention capacitor wiring 18nq are connected with each other in the other of the two pixels adjacent to each other in the row direction, (iii) the retention capacitor wiring 18nq and the retention capacitor wiring 18nr are connected with each other in one of two pixels that are adjacent to each other in the column direction, and (iv) the retention capacitor wiring 18np and the retention capacitor wiring 18nq are connected with each other in the other of the two pixels adjacent to each other in the column direction. The configurations illustrated in FIGS. 12 and 13 can reduce a range of changes in electric potential in each retention capacitor wiring and can prevent display unevenness accordingly. Note that a configuration of two pixels adjacent to each other in the row direction in each of the liquid crystal panels illustrated in FIGS. 12 and 13 is illustrated in FIG. 14.

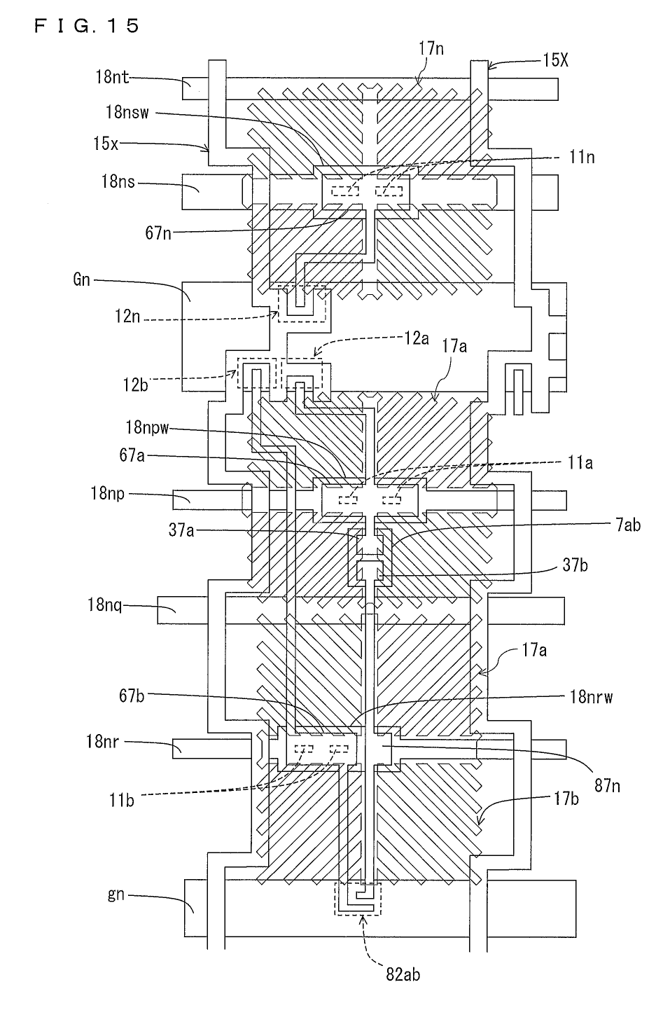

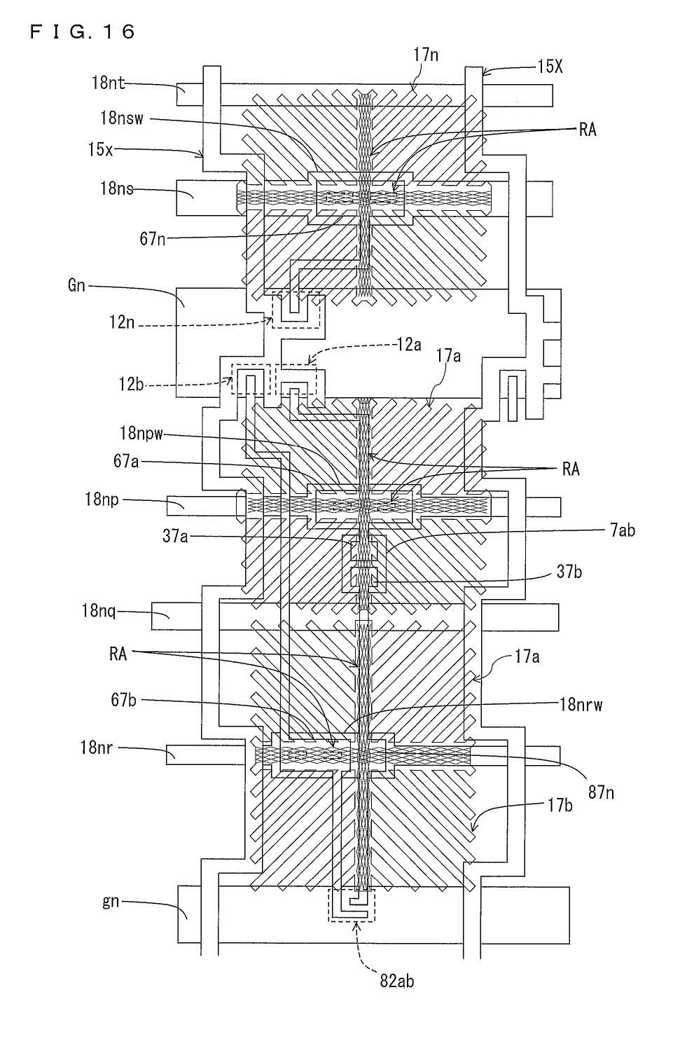

Each of the pixel electrodes in the liquid crystal panel illustrated in FIG. 10 can have a fishbone shape (PSA mode). This configuration is shown in FIG. 15. Also in the configuration illustrated in FIG. 15, cross-shape disclination (irregular orientation) areas, which are observed in the PSA mode, can be hidden (see FIG. 16). This is because (i) corresponding one(s) of the retention capacitor wiring and (ii) a corresponding one(s) of the extraction electrodes (and corresponding one(s) of the capacitor electrodes) crisscross.

### Embodiment 3

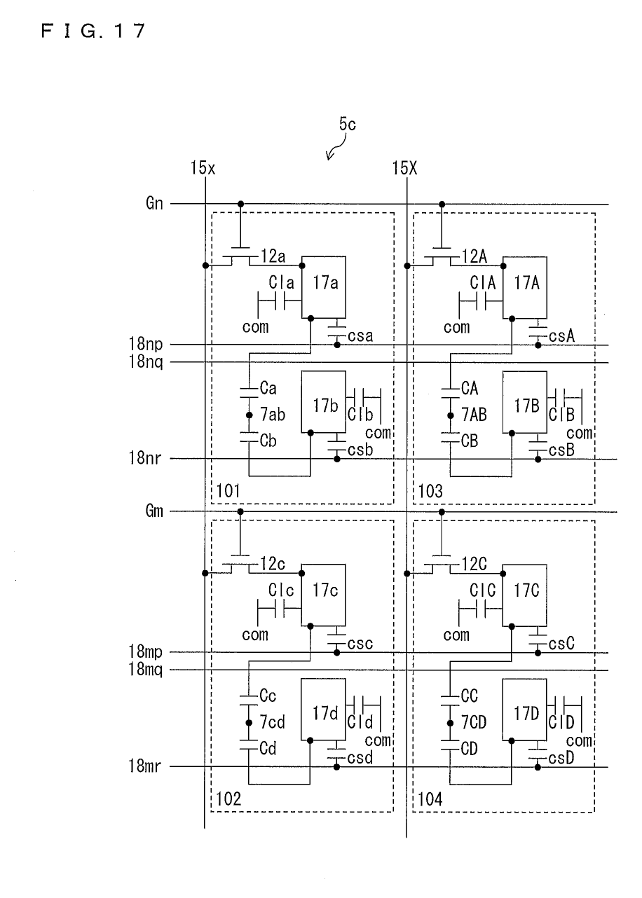

FIG. 17 is an equivalent circuit diagram of part of a liquid crystal panel 5c of the present embodiment. The liquid crystal panel 5c includes: a scanning signal line; a data signal line; and a first transistor connected with the scanning signal line, wherein (i) a first pixel electrode connected with a drain electrode of the first transistor, (ii) a second pixel electrode, (iii) a first capacitor electrode connected with the first pixel electrode, (iv) a second capacitor electrode connected with the second pixel electrode, and (v) a relay electrode which electrically floats are provided in each pixel area. The first capacitor electrode and the second capacitor electrode are provided in a same layer as the data signal line. The relay electrode is provided in a same layer as the scanning signal line. A capacitor is formed by the relay electrode and each of the first capacitor electrode and the second capacitor electrode.

For example, (i) a data signal line 15x is provided for a pixel column including pixels 101 and 102 arranged along the column direction, (ii) a data signal line 15X is provided for a pixel column including pixels 103 and 104 arranged along the column direction, (iii) a scanning signal line Gn and three retention capacitor wiring 18np, 18nq, and 18nr are provided for a pixel row including the pixels 101 and 103 arranged along the row direction, and (iv) a scanning signal line Gm and three retention capacitor wiring 18mp, 18mq, and 18mr are provided for the pixels 102 and 104 arranged along the row direction. Note that the scanning signal line Gn and the scanning signal line Gm are arranged in this order along the scanning direction.

In the pixel 101, for example, (i) two pixel electrodes 17a and 17b are arranged in this order along the column direction, (ii) a source electrode of a transistor 12a connected with the scanning signal line Gn is connected with the data signal line 15x, (iii) a drain electrode of the transistor 12a is connected with the pixel electrode 17a, (iv) a relay electrode 7ab and the pixel electrode 17a constitute a capacitor Ca, and (v) the relay electrode 7ab and the pixel electrode 17b form a capacitor Cb. Note that (i) a liquid crystal capacitor C1a is formed by the pixel electrode 17a and a common electrode (counter electrode) com, (ii) a liquid crystal capacitor C1b is formed by the pixel electrode 17b and the common electrode (counter electrode) com, (iii) a retention capacitor csa is formed by the pixel electrode 17a and the retention capacitor wiring 18np, and (iv) a retention capacitor csb is formed by the pixel electrode 17b and the retention capacitor wiring 18nr. Each of the pixels 102 through 104 has a configuration similar to the configuration above.

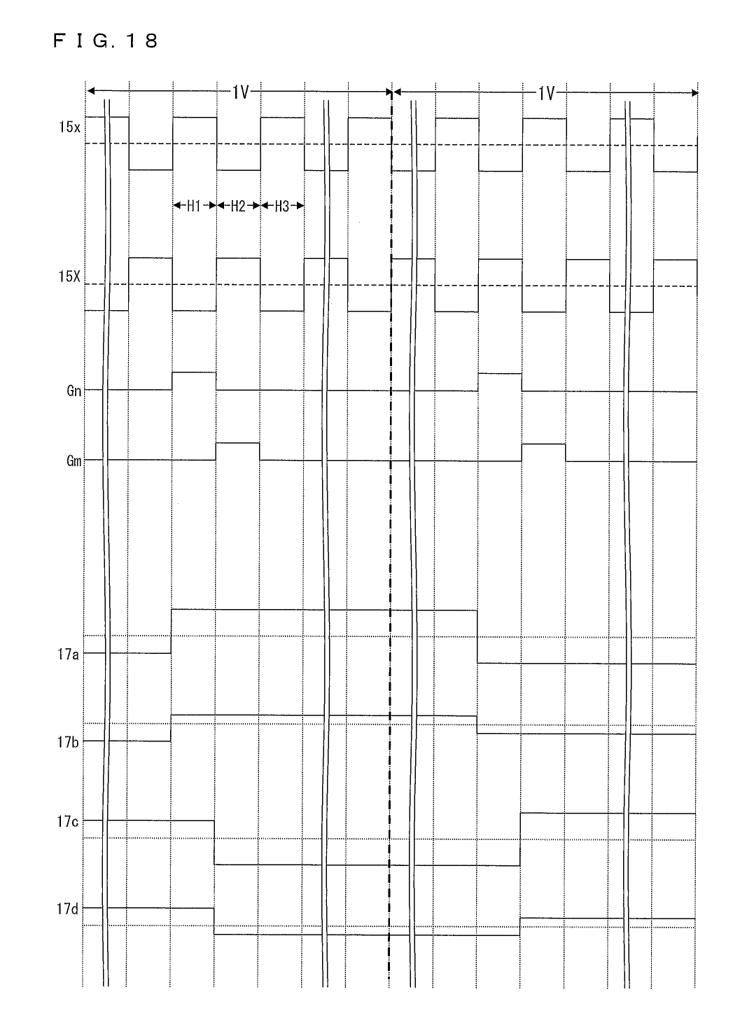

FIG. 18 is a timing chart (2 frames) showing a driving method employed in a case in which halftone solid display is carried out in a part (containing the pixels 101 and 102 illustrated in FIG. 17) of the liquid crystal panel 5c. 15x and 15X in FIG. 18 indicate data signals supplied to the respective data signal lines 15x and 15X illustrated in FIG. 17. Gn and Gm in FIG. 18 indicate scanning signals (active High) supplied to the respective scanning signal lines Gn and Gm illustrated in FIG. 18. 17a through 17d in FIG. 18 indicate electric potentials of the respective pixel electrodes 17a through 17d illustrated in FIG. 17.

In the driving method shown by FIG. 18, (i) the scanning signal lines are sequentially selected one by one and (ii) data signals having reverse polarities to each other are supplied to respective two adjacent data signal lines (e.g. 15x and 15X). Note that polarities of data signals supplied to respective data signal lines are reversed every horizontal scan period (1H).

For example, during a horizontal scan period H1 out of three consecutive horizontal scan periods H1 through H3, the scanning signal line Gn is selected (activated). This causes a plus data signal to be written into the pixel electrodes 17a as shown in FIG. 18. Note that the pixel electrode 17b (i) is connected with the pixel electrode 17a via the capacitors Ca and Cb (combined capacitance=Ca×Cb/Ca+Cb), which are connected with each other in series. As such, an electric potential of the pixel electrode 17b becomes closer to a center electric potential than an electric potential of the pixel electrode 17a is. As a result, a subpixel corresponding to the pixel electrode 17a becomes a bright subpixel (+) and a subpixel corresponding to the pixel electrode 17b becomes a dark subpixel (+).

Subsequently, during H2, the scanning signal line Gm is selected (activated). This causes a minus data signal to be written into the pixel electrode 17c as shown in FIG. 18. Note that the pixel electrode 17d (i) is connected with the pixel electrode 17c via the capacitors Cc and Cd (combined capacitance=Cc×Cd/Cc+Cd), which are connected with each other in series. As such, an electric potential of the pixel electrode 17d becomes closer to the center electric potential than an electric potential of the pixel electrode 17c is. As a result, a subpixel corresponding to the pixel electrode 17c becomes a bright subpixel (−) and a subpixel corresponding to the pixel electrode 17d becomes a dark subpixel (−).

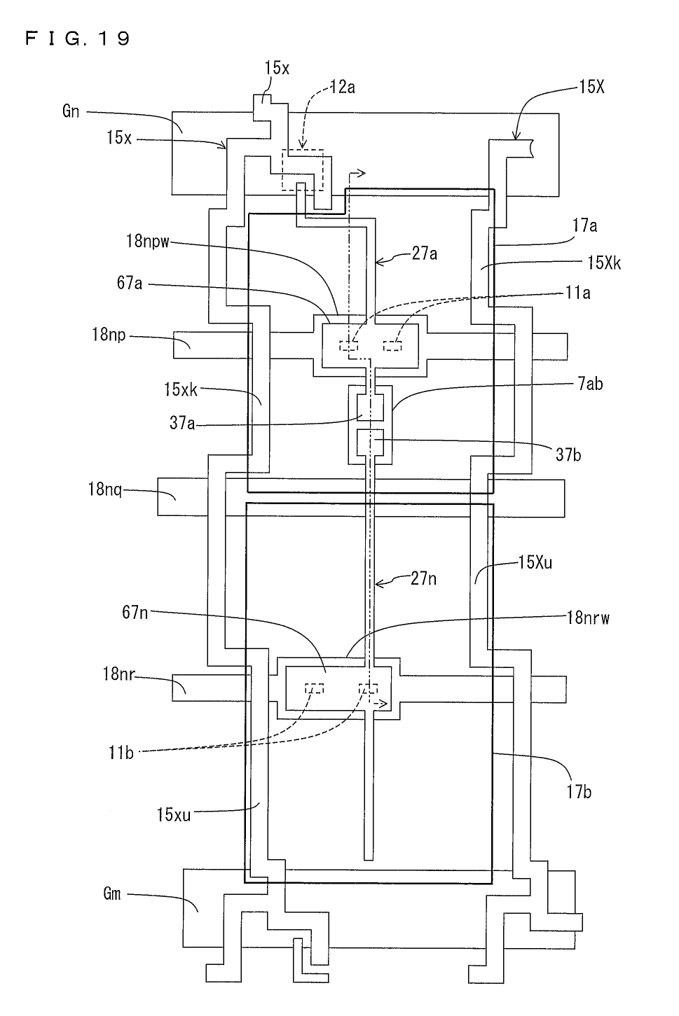

FIG. 19 is a plan view illustrating an exemplary configuration of one (1) pixel in the liquid crystal panel 5c illustrated in FIG. 17. As illustrated in FIG. 19, in the liquid crystal panel 5c, the pixel electrodes 17a and 17b, each of which has a substantially rectangular shape, are arranged in this order along the column direction in an area defined by the scanning signal line Gn and the data signal line 15x, (ii) the retention capacitor wiring 18np is provided so as to traverse the pixel electrode 17a at the center of the pixel electrode 17a, (iii) the retention capacitor wiring 18nr is provided so as to traverse the pixel electrode 17b at the center of the pixel electrode 17b, and (iv) the retention capacitor wiring 18nq is provided so as to overlap a gap between the pixel electrodes 17a and 17b.

The transistors 12a is provided near at an intersection of the scanning signal line Gn and the data signal line 15x. The source electrode of the transistor 12a is connected with the data signal line 15x. The drain electrode of the transistor 12a is connected with an extraction (draw-out) electrode 27a. The extraction electrode 27a is provided, below a longitudinal center line of the pixel electrode 17a, so as to be connected with a capacitor electrode 37a provided below the pixel electrode 17a (i.e., the extraction electrode 27a is connected with the capacitor electrode 37a in a same layer as the capacitor electrode 37a). The extraction electrode 27a has an expansive part 67a below a central part of the pixel electrode 17a. The expansive part 67a and the pixel electrode 17a are connected with each other, via two contact holes 11a. The retention capacitor wiring 18np has a wide part 18npw below the pixel electrode 17a. The expansive part 67a and the wide part 18npw overlap each other via a gate insulating film. Such overlapping causes the capacitor csa (see FIG. 17) to be formed.

An extraction electrode 27n is provided below a longitudinal center line of the pixel electrode 17b and leads to a capacitor electrode 37b provided below the pixel electrode 17a (i.e., the extraction electrode 27n is connected with the capacitor electrode 37b in a same layer as the capacitor electrode 37b). The extraction electrode 27n has an expansive part 67n below a central part of the pixel electrode 17b. The expansive part 67n is connected with the pixel electrode 17b, via two contact holes 11b. The retention capacitor wiring 18nr also has a wide part 18nrw below the pixel electrode 17b. The expansive part 67n and the wide part 18nrw overlap each other via the gate insulating film. Such overlapping causes the capacitor csb (see FIG. 17) to be formed.

Below the longitudinal center line of the pixel electrode 17a, the relay electrode 7ab is provided, in a form of a floating island, in a same layer as the scanning signal lines and the capacitor wiring. The relay electrode 7ab and the capacitor electrode 37a overlap each other, via the gate insulating film. Such overlapping causes the capacitor Ca (see FIG. 17) to be formed. The relay electrode 7ab and the capacitor electrode 37b overlap each other, via the gate insulating film. Such overlapping causes the capacitor Cb (see FIG. 17) to be formed.

The data signal line 15x extends so as to meander along the column direction. Parts 15xk and 15xu of the data signal line 15x respectively overlap (i) an edge part which is a lower left part of the pixel electrode 17a in FIG. 19 and (ii) an edge part which is a lower left part of the pixel electrode 17b in FIG. 19. The data signal line 15X also extends so as to meander along the column direction. Parts 15Xk and 15Xu of the data signal line 15X respectively overlap (i) another edge part which is an upper right part of the pixel electrode 17a in FIG. 19 and (ii) another edge part which is an upper right part of the pixel electrode 17b in FIG. 19.

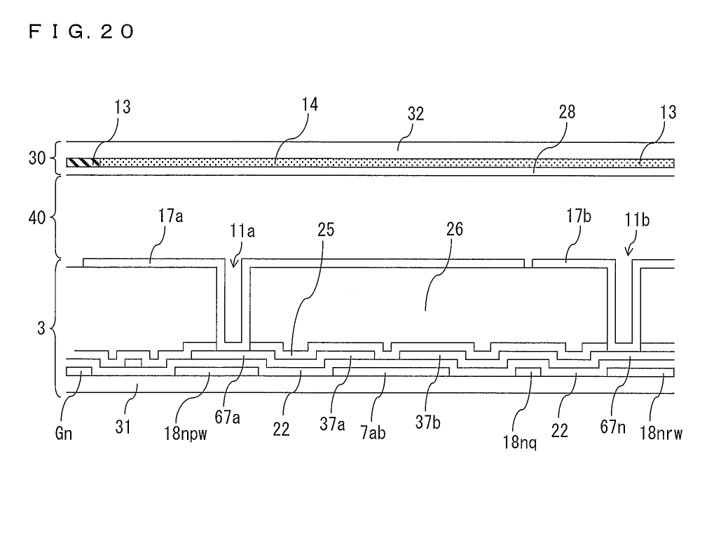

FIG. 20 is a cross-sectional view taken along a line indicated by arrows of FIG. 19. As illustrated in FIG. 20, the liquid crystal panel 5c includes (i) an active matrix substrate 3, (ii) a color filter substrate 30 facing the active matrix substrate 3, and (iii) a liquid crystal layer 40 provided between both of the substrates (3 and 30).

In the color filter substrate 30, (i) a black matrix 13 and a colored layer 14 are provided on a glass substrate 32 and (ii) a common electrode (com) 28 is provided on the black matrix 13 and the colored layer 14. Note that the liquid crystal layer 30 is constituted by, for example, liquid crystal of an optical alignment mode (4 domains) which has been subjected to an alignment treatment by means of ultraviolet ray.

In the active matrix substrate 3, (i) the scanning signal line Gn, the relay electrode 7ab, and the retention capacitor wiring 18np (18npw), 18nq, and 18nr (18nrw) are provided on a glass substrate 31 and (ii) a gate insulating film 22 which, for example, has a thickness of 200 nm and made from SiNx is provided so as to cover the scanning signal line Gn, the relay electrode 7ab, and the retention capacitor wiring 18np (18npw), 18nq, and 18nr (18nrw). On the gate insulating film 22, (i) semiconductor layers (i-layer and n+ layer), (ii) a source electrode and a drain electrode which are in contact with the n+ layer, (iii) the extraction electrode 27a (expansive part 67a), (iv) the capacitor electrodes 37a and 37b, and (v) the extraction electrode 27n (expansive part 67n) are formed by, for example, Ti and Al (the semiconductor layers, the source electrode, and the drain electrode are not included in the cross-section and are therefore not shown in FIG. 20). An inorganic interlayer insulating film 25 made from, for example, SiNx is provided so as to cover the semiconductor layers (i-layer and n+ layer), the source electrode, the drain electrode, the extraction electrode 27a (expansive part 67a), the capacitor electrodes 37a and 37b, and the extraction electrode 27n (expansive part 67n). An organic interlayer insulating film 26 with a thickness (about 2μ) larger than that of the inorganic interlayer insulating film 25 is provided on the inorganic interlayer insulating film 25. The pixel electrodes 17a and 17b are provided on the organic interlayer insulating film 26. Each of the contact holes 11a is formed by hollowing out the inorganic interlayer insulating film 25 and the organic interlayer insulating film 26. This causes the pixel electrode 17a and the expansive part 67a (of the extraction electrode 27a) to be connected with each other. Each of the contact holes 11b is formed by hollowing out the inorganic interlayer insulating film 25 and the organic interlayer insulating film 26. This causes the pixel electrode 17b and the expansive part 67n (of the extraction electrode 27n) to be connected with each other.

The formation of the capacitor csa (see FIG. 17) is caused by the overlapping, merely via the gate insulating film 22, of the expansive part 67a and the wide part 18npw (of the retention capacitor wiring 18np). The formation of the capacitor csb (see FIG. 17) is caused by the overlapping, merely via the gate insulating film 22, of the expansive part 67n and the wide part 18nrw (of the retention capacitor wiring 18nr).

The formation of the capacitor Ca (see FIG. 17) is caused by the overlapping, merely via the gate insulating film 2, of (i) the relay electrode lab provided in the same layer as the scanning signal line Gn and (ii) the capacitor electrode 37a. The formation of the capacitor Cb (see FIG. 17) is caused by the overlapping, merely via the gate insulating film 22, of the relay electrode lab and the capacitor electrode 37b.

According to the liquid crystal panel of the present embodiment, it is thus possible to (i) provide the organic interlayer insulating film 26 with a large thickness and (ii) secure sufficiently large capacitances of the respective capacitors Ca, Cb and Cn. It accordingly becomes possible to have a high-aperture-ratio structure in which edges of the pixel electrodes 17a and 17b overlap the data signal lines 15x and 15X and the scanning signal lines Gn and Gm.

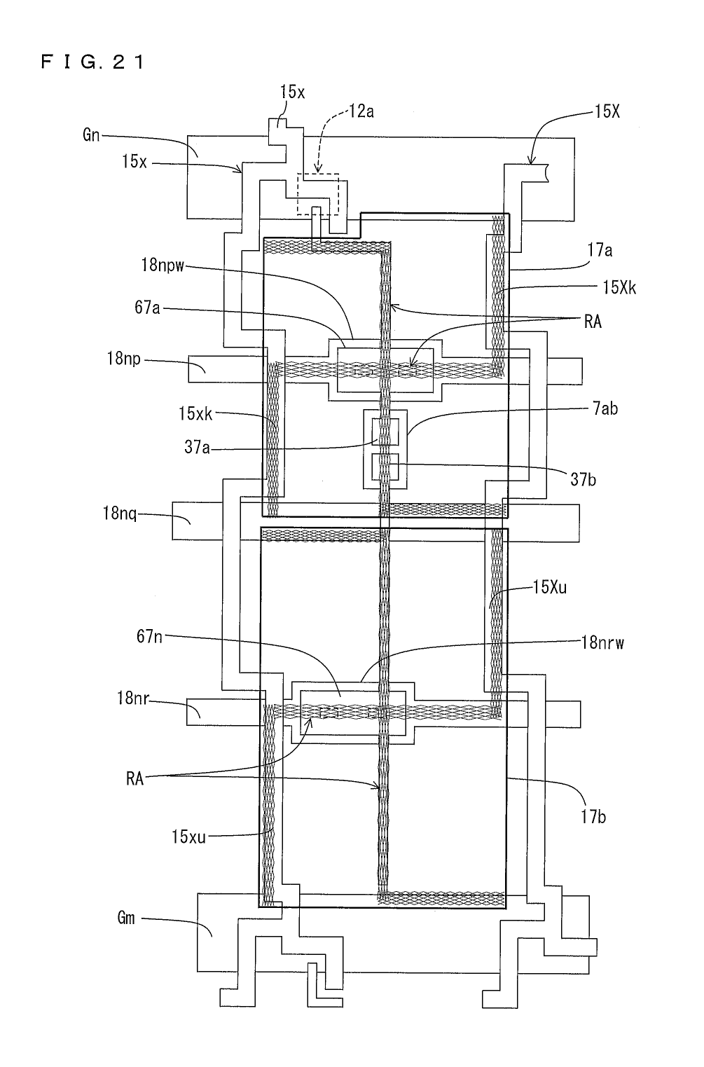

Below each pixel electrode, (i) corresponding ones of the retention capacitor wiring and (ii) a corresponding one(s) of the extraction electrodes (and corresponding ones of the capacitor electrodes) crisscross, and each of the data signal lines meanders so as to overlap edges of the pixel electrodes. This configuration allows swastika-shaped disclination (irregular orientation) areas, which are observed in a case of using liquid crystal of an optical alignment mode, to be hidden (see FIG. 21).

In addition, since the liquid crystal panel 5c employs the 1-transistor capacitive coupling type pixel division system, the liquid crystal panel 5c (i) has a good viewing angle characteristic and (ii) has a configuration simpler than that of a liquid crystal panel of the 3-transistor capacitive coupling type.

The present invention is not limited to the above-described embodiments. An embodiment obtained by appropriately modifying the embodiments on the basis of common technical knowledge and an embodiment obtained by combining modified embodiments will also be included in the embodiments of the present invention.

### INDUSTRIAL APPLICABILITY

The liquid crystal panel of and the active matrix substrate of the present invention are suitable, for example, for a liquid crystal TV.

### REFERENCE SIGNS LIST

5a through 5c: liquid crystal panel
12a through 12d and 12A through 12D: transistor
12i, 12j, 12I, and 12J: transistor
15x and 15X: data signal line
Gm, Gn, and Gk: scanning signal line
18ip, 18iq, 18ir, 18is, and 18it: retention capacitor wiring
22: gate insulating film
25: inorganic insulating film
26: organic insulating film
101 through 104: pixel
601: television receiver
800: liquid crystal display device

1. An active matrix substrate comprising:
a scanning signal line;
a data signal line;
a first transistor connected with the scanning signal line and the data signal line;
a second transistor connected with the scanning signal line and the data signal line; and
a third transistor connected with another scanning signal line which is different from the scanning signal line,
wherein (i) a first pixel electrode connected with the first transistor, (ii) a second pixel electrode connected with the second transistor, (iii) a first capacitor electrode connected with the first pixel electrode, (iv) a second capacitor electrode connected with the second pixel electrode via the third transistor, and (v) a relay electrode are provided in each pixel area,
the first capacitor electrode and the second capacitor electrode are provided in a same layer as the data signal line,
the relay electrode is provided in a same layer as the scanning signal line and the another scanning signal line, and
the relay electrode and each of the first capacitor electrode and the second capacitor electrode overlap each other, via a gate insulating film.

2. An active matrix substrate as set forth in claim 1, further comprising retention capacitor wiring,
a capacitor being formed by the retention capacitor wiring and the second capacitor electrode.

3. The active matrix substrate as set forth in claim 1, wherein an interlayer insulating film is provided on channels of the respective first through third transistors, the interlayer insulating film including an organic insulating film.

4. The active matrix substrate as set forth in claim 1, wherein the scanning signal line with which each of the first transistor and the second transistor is connected and the another scanning signal line with which the third transistor is connected are arranged adjacent to each other in this order along a scanning direction.

5. The active matrix substrate as set forth in claim 1, wherein each of the first pixel electrode and the second pixel electrode overlaps the data signal line.

6. The active matrix substrate as set forth in claim 5, wherein the data signal line meanders so that (i) the data signal line and (ii) an edge part of each of the first pixel electrode and the second pixel electrode overlap each other.

7. An active matrix substrate as set forth in claim 1, further comprising:
an extraction electrode which is extracted from the first transistor so as to be connected with the first capacitor electrode; and
an extraction electrode which is extracted from the third transistor so as to be connected with the second capacitor electrode,
the first pixel electrode and the second pixel electrode being arranged along a longitudinal direction in the each pixel area, a lateral direction being a direction along which the scanning signal line and the another scanning signal line extend,
the extraction electrodes, the first capacitor electrode, and the second capacitor electrode being provided so as to longitudinally run through the each pixel area.

8. An active matrix substrate as set forth in claim 1, further comprising:
first retention capacitor wiring provided so as to traverse the first pixel electrode in a lateral direction, which is a direction along which the scanning signal line and the another scanning signal line extend;
second retention capacitor wiring provided so as to traverse the second pixel electrode in the lateral direction; and
third retention capacitor wiring provided so that (i) the third retention capacitor wiring and (ii) a gap between the first pixel electrode and the second pixel electrode overlap each other.

9. The active matrix substrate as set forth in claim 8, wherein the second capacitor electrode and the second retention capacitor wiring form a capacitor.

10. The active matrix substrate as set forth in claim 8, wherein (i) the first retention capacitor wiring or the second retention capacitor wiring and (ii) the third retention capacitor wiring are connected with each other.

11. The active matrix substrate as set forth in claim 10, wherein:
the first retention capacitor wiring and the third retention capacitor wiring are connected with each other in a pixel area corresponding to a color, and
the second retention capacitor wiring and the third retention capacitor wiring are connected with each other in a pixel area corresponding to another color.

12. The active matrix substrate as set forth in claim 10, wherein:
the first retention capacitor wiring and the third retention capacitor wiring are connected with each other in one of two pixel areas adjacent to each other in the lateral direction,
the second retention capacitor wiring and the third retention capacitor wiring are connected with each other in the other of the two pixel areas adjacent to each other in the lateral direction,
the first retention capacitor wiring and the third retention capacitor wiring are connected with each other in one of two pixel areas adjacent to each other in a longitudinal direction, and
the second retention capacitor wiring and the third retention capacitor wiring are connected with each other in the other of the two pixel areas adjacent to each other in the longitudinal direction.

13. An active matrix substrate as set forth in claim 1, further comprising:
a fourth transistor connected with the scanning signal line with which each of the first transistor and the second transistor are connected; and
a third pixel electrode connected with the fourth transistor.

14. The active matrix substrate as set forth in claim 1, wherein each of the first pixel electrode and the second pixel electrode has a fishbone shape.

15. An active matrix substrate comprising:
a scanning signal line;
a data signal line; and
a first transistor connected with the scanning signal line and the data signal line,
wherein (i) a first pixel electrode connected with the first transistor, (ii) a second pixel electrode, (iii) a first capacitor electrode connected with the first pixel electrode, (iv) a second capacitor electrode connected with the second pixel electrode, and (v) a relay electrode are provided in each pixel area,
the first capacitor electrode and the second capacitor electrode are provided in a same layer as the data signal line,
the relay electrode is provided in a same layer as the scanning signal line, and
the relay electrode and each of the first capacitor electrode and the second capacitor electrode overlap each other, via a gate insulating film.

16. An active matrix substrate comprising:
a scanning signal line;
a data signal line;
a first transistor connected with the scanning signal line and the data signal line;
a second transistor connected with the scanning signal line and the data signal line;
a third transistor connected with another scanning signal line which is different from the scanning signal line;
a fourth transistor connected with the scanning signal line with which each of the first transistor and the second transistor is connected; and
retention capacitor wiring,
wherein (i) a first pixel electrode connected with the first transistor, (ii) a second pixel electrode connected with the second transistor, (iii) a third pixel electrode connected with the fourth transistor, and (iv) a coupling electrode are provided in each pixel area, a capacitor being formed by the coupling electrode and each of the first pixel electrode and the retention capacitor wiring, and
the coupling electrode is connected with the second pixel electrode, via the third transistor.

17. A liquid crystal panel comprising:
an active matrix substrate recited in claim 1; and
a liquid crystal layer.

18. The liquid crystal panel as set forth in claim 17, wherein the liquid crystal layer is subjected to an alignment treatment by means of ultraviolet ray.

19. A television receiver comprising:
a liquid crystal display device including a liquid crystal panel recited in claim 17; and
a tuner section for receiving a television broadcast.
